(19) United States
(12) Patent Application Publication
(10) Pub. No.: US 2025/0184637 A1
(43) Pub. Date: Jun. 5, 2025

(54) PHOTODETECTION DEVICE

(71) Applicant: SONY SEMICONDUCTOR SOLUTIONS CORPORATION, KANAGAWA (JP)

(72) Inventor: KAZUKI HIZU, KANAGAWA (JP)

(21) Appl. No.: 18/842,434

(22) PCT Filed: Jan. 19, 2023
(86) PCT No.: PCT/JP2023/001547

§ 371 Date: Aug. 29, 2024

(30) Foreign Application Priority Data
Mar. 10, 2022 (JP) 2022-037314

(51) Int. Cl. H04N 25/773; H04N 25/768

(52) U.S. Cl. CPC H04N 25/773; H04N 25/768

(57) ABSTRACT

A photodetection device according to an embodiment of the present disclosure includes: a light-receiving element configured to receive light and generate a signal; a generation section configured to generate a first signal based on the signal generated by the light-receiving element; and a control section configured to control supply of electric current to the light-receiving element on the basis of pulse width of the first signal.

### TECHNICAL FIELD

The present disclosure relates to a photodetection device.

### BACKGROUND ART

There has been proposed a photodetection device that controls a recharge current to be supplied to a single-photon avalanche diode (SPAD) and performs photodetection (see PTL 1).

### CITATION LIST

### Patent Literature

PTL 1: WO2020/116158

### SUMMARY OF THE INVENTION

The photodetection device has been desired to improve its detection performance.

It has been desired to provide a photodetection device having good detection performance.

A photodetection device according to an embodiment of the present disclosure includes: a light-receiving element configured to receive light and generate a signal; a generation section configured to generate a first signal based on the signal generated by the light-receiving element; and a control section configured to control supply of electric current to the light-receiving element on the basis of pulse width of the first signal.

### BRIEF DESCRIPTION OF DRAWING

FIG. 1 is a diagram illustrating an example of a schematic configuration of a photodetection device according to a first embodiment of the present disclosure.

FIG. 2 is a diagram illustrating a configuration example of a pixel and a control section of the photodetection device according to the first embodiment of the present disclosure.

FIG. 3 is a diagram illustrating a configuration example of a pixel and a control section of the photodetection device according to the first embodiment of the present disclosure.

FIG. 4 is a flowchart illustrating an operation example of the photodetection device according to the first embodiment of the present disclosure.

FIG. 5 is a diagram for describing control over pulse width by the photodetection device according to the first embodiment of the present disclosure.

FIG. 6 is a diagram for describing an example of timing of executing a process by the photodetection device according to the first embodiment of the present disclosure.

FIG. 7 is a diagram for describing control over pulse width by the photodetection device according to the first embodiment of the present disclosure.

FIG. 8 is a diagram illustrating a configuration example of a detection section of a photodetection device according to a first modification of the present disclosure.

FIG. 9 is a timing diagram illustrating an operation example of the detection section of the photodetection device according to the first modification of the present disclosure.

FIG. 10 is a diagram illustrating a configuration example of a detection section of a photodetection device according to a second modification of the present disclosure.

FIG. 11 is a timing diagram illustrating an operation example of the detection section of the photodetection device according to the second modification of the present disclosure.

FIG. 12 is a diagram illustrating a configuration example of a detection section of a photodetection device according to a third modification of the present disclosure.

FIG. 13 is a timing diagram illustrating an operation example of the detection section of the photodetection device according to the third modification of the present disclosure.

FIG. 14 is a diagram illustrating another configuration example of the detection section of the photodetection device according to the third modification of the present disclosure.

FIG. 15 is a timing diagram illustrating another operation example of the detection section of the photodetection device according to the third modification of the present disclosure.

FIG. 16 is a diagram illustrating a configuration example of a signal determination section of a photodetection device according to a fourth modification of the present disclosure.

FIG. 17 is a diagram illustrating a configuration example of pixels and a control section of a photodetection device according to a fifth modification of the present disclosure.

FIG. 18 is a diagram illustrating another configuration example of the pixels and the control section of the photodetection device according to the fifth modification of the present disclosure.

FIG. 19 is a diagram illustrating another configuration example of the pixels and the control section of the photodetection device according to the fifth modification of the present disclosure.

FIG. 20 is a diagram illustrating a configuration example of pixels and a control section of a photodetection device according to a sixth modification of the present disclosure.

FIG. 21 is a diagram illustrating a configuration example of a pixel and a control section of a photodetection device according to a seventh modification of the present disclosure.

FIG. 22 is a diagram illustrating a configuration example of a pixel and a control section of a photodetection device according to an eighth modification of the present disclosure.

FIG. 23 is a diagram illustrating a configuration example of a pixel and a control section of a photodetection device according to the eighth modification of the present disclosure.

FIG. 24 is a diagram illustrating a configuration example of a pixel and a control section of a photodetection device according to a ninth modification of the present disclosure.

FIG. 25 is a diagram illustrating a configuration example of a delay section of the photodetection device according to the ninth modification of the present disclosure.

FIG. 26 is a diagram illustrating another configuration example of the delay section of the photodetection device according to the ninth modification of the present disclosure.

FIG. 27 is a diagram illustrating a configuration example of a pixel and a control section of a photodetection device according to a tenth modification of the present disclosure.

FIG. 28 is a diagram for describing an example of timing of executing a process by the photodetection device according to the tenth modification of the present disclosure.

FIG. 29 is a diagram for describing another example of timing of executing a process by the photodetection device according to the tenth modification of the present disclosure.

FIG. 30 is a diagram illustrating a configuration example of a pixel and a control section of a photodetection device according to a second embodiment of the present disclosure.

FIG. 31 is a diagram illustrating a configuration example of a generation section of the photodetection device according to the second embodiment of the present disclosure.

FIG. 32 is a block diagram depicting an example of schematic configuration of a vehicle control system.

FIG. 33 is a diagram of assistance in explaining an example of installation positions of an outside-vehicle information detecting section and an imaging section.

FIG. 34 is a view depicting an example of a schematic configuration of an endoscopic surgery system.

FIG. 35 is a block diagram depicting an example of a functional configuration of a camera head and a camera control unit (CCU).

### MODES FOR CARRYING OUT THE INVENTION

Next, with reference to drawings, details of embodiments of the present disclosure will be described. It is to be noted that the description will be given in the following order.
1. First Embodiment
2. Second Embodiment
3. Usage Example
4. Application Example

### 1. First Embodiment

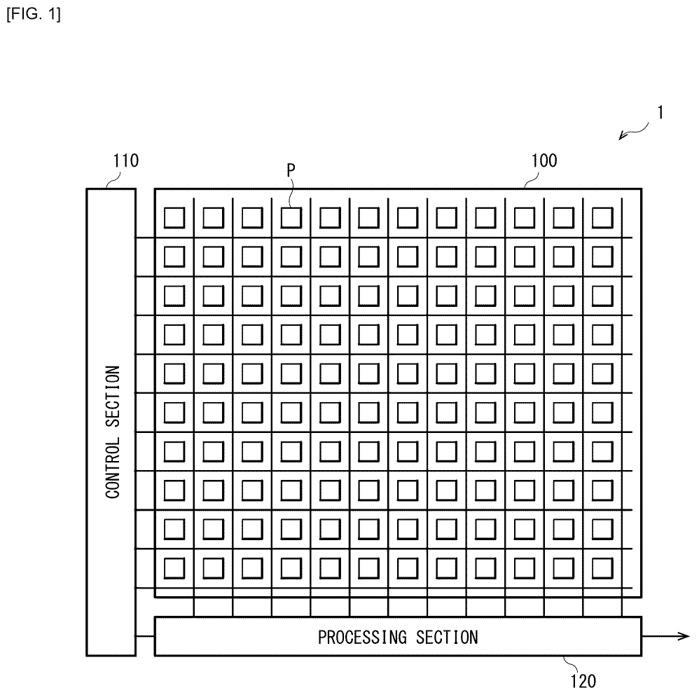

FIG. 1 is a diagram illustrating an example of a schematic configuration of a photodetection device according to a first embodiment of the present disclosure. A photodetection device 1 is a device that makes it possible to detect incident light. The photodetection device 1 includes a plurality of pixels P having a light-receiving element, and is configured to perform photoelectric conversion on the incident light and generate a signal. The photodetection device 1 may be applied to ranging sensors that makes it possible to measure a distance by using a time-of-flight (TOF) method, other ranging devices, and the like.

In an example illustrated in FIG. 1, the photodetection device 1 includes a region (pixel section 100) where the plurality of pixels P is two-dimensionally arranged in a matrix form. For example, the light-receiving element (light-receiving section) of each pixel P is an SPAD element. The photodetection device 1 takes in incident light (image light) from a measurement target via an optical system (not illustrated) including an optical lens. The light-receiving element may receive light and generate electric charge through the photoelectric conversion.

The photodetection device 1 includes a control section 110 and a processing section 120. The control section 110 is configured to control operation of respective sections of the photodetection device 1. The control section 110 is implemented by a plurality of circuits including a shift register, an address decoder, and the like. The control section 110 generates signals to drive the pixels P and outputs the signals to the respective pixels P in the pixels section 100. For example, the control section 110 supplies control signals to the respective pixels P in the pixel section, controls the respective pixels P, and causes the pixel section 100 to output signals of the respective pixels P.

The processing section 120 is a signal processing section and is configured to process a signal output from each pixel P. For example, the processing section 120 includes a processor and memory, and performs the signal processing. For example, the processing section 120 is a digital signal processor (DSP). It is to be noted that it is also possible to integrate the processing section 120 and the control section 110. The processing section 120 may perform various kinds of signal processing on the signals of the respective pixels and generate information related to a distance to the measurement target.

As an example, the photodetection device 1 receives light reflected by the measurement target in a case where a light source (not illustrated) emits light (for example, laser light) to the measurement target. Each pixel P of the photodetection device 1 receives light reflected by the measurement target and generate a signal in response to incidence of a photon. The signal of the pixel P is a signal depending on a distance to the measurement target. The control section 110 reads out the signal and outputs the signal to the processing section 120.

The processing section 120 of the photodetection device 1 estimates a phase difference between the emitted light and the reflected light, that is, round trip time of light on the basis of the generated signals of the pixels, and calculate a distance between the photodetection device 1 and a subject. The distance to the measurement target is computed on the basis of time it takes light emitted from the light source to get reflected by the measurement target and reach the photodetection device 1. The processing section 120 may detect distances to the target with regard to the respective pixels P, and generate image data related to the distances to the target.

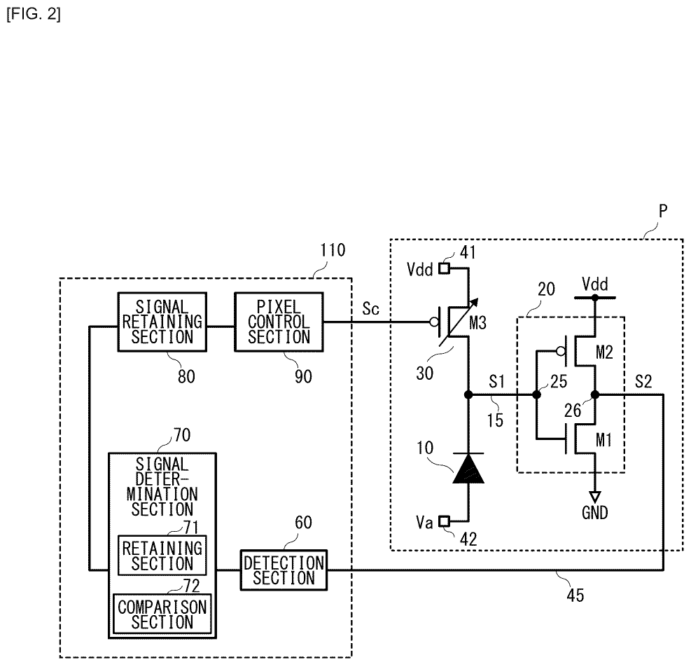

FIG. 2 is a diagram illustrating a configuration example of a pixel and a control section of the photodetection device according to the first embodiment of the present disclosure. A pixel P of the photodetection device 1 includes a light-receiving element 10, a generation section 20, and a supply section 30. The light-receiving element 10 is configured to receive light and generate a signal. The light-receiving element 10 may be an SPAD element, convert incident photons into electric charge, and output a signal S1 that is an electric signal corresponding to the incident photons.

For example, the light-receiving element 10 is electrically coupled to an electric power source line, a terminal, and the like. The electric power source line makes it possible to supply predetermined voltage. In the example illustrated in FIG. 2, the light-receiving element 10 has an electrode that is a cathode electrically coupled to a first terminal 41 via the supply section 30. For example, the first terminal 41 is given power source voltage Vdd from a voltage source via the electric power source line. The light-receiving element 10 also has another electrode that is an anode electrically coupled to a second terminal 42, which is supplied with power source voltage Va (hereinafter, also referred to as anode voltage Va). For example, the second terminal 42 is given the power source voltage Va from a voltage source via the electric power source line.

By the anode voltage Va and voltage supplied via the supply section 30, voltage corresponding to a potential difference larger than breakdown voltage of the light-receiving element 10 may be applied between the cathode and the anode of the light-receiving element 10. In other words, a potential difference between both ends of the light-receiving element 10 may be set to the potential difference larger than the breakdown voltage. When reverse bias voltage that is larger than the breakdown voltage is given, the light-receiving element 10 enters a state where that makes it possible to operate in a Geiger mode. In the Geiger mode, the light-receiving element 10 may cause avalanche multiplication in response to incidence of a photon, and generate pulsed electric current. In the pixel P, the signal S1 depending on the electric current flowing through the light-receiving element 10 in response to incident of a photon is output to the generation section 20.

The generation section 20 is configured to generate a signal S2 based on the signal S1 generated by the light-receiving element 10. In the example illustrated in FIG. 2, the generation section 20 is implemented by an inverter. The generation section 20 includes a transistor M1 and a transistor M2 that are in serial connection. The generation section 20 includes an input section 25 and an output section 26, and outputs an inversion signal of an input signal. The input section 25 of the generation section 20 is coupled to a node 15 that couples the supply section 30 to the light-receiving element 10. In the example illustrated in FIG. 2, the input section 25 of the generation section 20 is electrically coupled to the supply section 30 and the cathode of the light-receiving element 10, while the output section 26 of the generation section 20 is electrically coupled to a signal line 45.

Each of the transistors M1 and M2 is an MOS transistor (MOSFET) having gate, source, and drain terminals. The transistor M1 is an NMOS transistor, while the transistor M2 is a PMOS transistor. The respective gates of the transistors M1 and M2 are electrically coupled to each other, which configure the input section 25. The respective gates of the transistors M1 and M2 are coupled to the node 15. The source of the transistor M1 is coupled to an earthing wire (ground wire). The source of the transistor M2 is coupled to an electric power source line supplied with the power source voltage Vdd. The drain of the transistor M1 and the drain of the transistor M2 are electrically coupled to each other, which configure the output section 26.

The signal S1 is input from the light-receiving element 10 to the generation section 20. The signal S1 has a signal level, i.e., voltage (electric potential) of the node 15, that varies depending on electric current flowing through the light-receiving element 10. In the example illustrated in FIG. 2, the light-receiving element 10 and the supply section 30 input the signal S1 having cathode voltage of the light-receiving element 10 to the input section 25 of the generation section 20. For example, in a case where voltage of the signal S1 is higher than a threshold, the generation section 20 outputs a signal S2 having a low level. Alternatively, in a case where voltage of the signal S1 is lower than the threshold, the generation section 20 outputs a signal S2 having a high level.

In the example illustrated in FIG. 2, the inverter serving as the generation section 20 causes the voltage of the signal S2 to transition from the low level to the high level when the voltage of the signal S1 becomes lower than the threshold voltage of the inverter in response to reception of a photon by the light-receiving element 10. It is to be noted that the generation section 20 may be implemented by a buffer circuit, an AND circuit, a comparator circuit, or the like.

The supply section 30 is configured to supply electric current to the light-receiving element 10. The supply section 30 may be electrically coupled to the first terminal 41 that is given the power source voltage Vdd, and may supply electric current and voltage to the light-receiving element 10. The supply section 30 supplies electric current to the light-receiving element 10 in a case where the avalanche multiplication happens and a potential difference between the electrodes of the light-receiving element 10 may is smaller than the breakdown voltage. The supply section 30 recharges the light-receiving element 10, and causes the light-receiving element 10 to enter a state of being operable in the Geiger mode.

In the example illustrated in FIG. 2, the generation section 30 is implemented by a transistor M3. For example, the transistor M3 is a PMOS transistor. One of source or drain of the transistor M3 is coupled to the cathode of the light-receiving element 10. The other of source or drain of the transistor M3 is coupled to the first terminal 41. The transistor M3 may generate electric current based on a signal Sc input from the control section 110, and may supply the generated electric current to the light-receiving element 10. The transistor M3 makes it possible to supply the light-receiving element 10 with electric current corresponding to the signal level of the signal Sc. The supply section 30 can be said as a recharge section that recharges the light-receiving element 10 with electric charge to recharge the voltage of the light-receiving element 10.

As described above, when a photon enters the light-receiving element 10 and this causes the avalanche multiplication, the electric current flowing through the light-receiving element 10 increases and the potential difference between the cathode and the anode of the light-receiving element 10 decreases. In the example illustrated in FIG. 2, cathode voltage of the light-receiving element 10 decreases, and voltage of the signal S1 that enters the generation section 20 decreases. The potential difference between the electrodes of the light-receiving element 10 becomes smaller than the breakdown voltage, and this stops (quenches) the avalanche multiplication. With the decrease of voltage of the signal S1, the generation section 20 causes voltage of the signal S2 to transition from the low level to the high level.

The potential difference between the electrodes of the light-receiving element 10 increases when the supply section 30 supplies electric current (recharge current) to the light-receiving element 10. In the example illustrated in FIG. 2, cathode voltage of the light-receiving element 10, that is, voltage of the signal S1 increases. When the potential difference between the electrodes of the light-receiving element 10 becomes larger than the breakdown voltage, the light-receiving element 10 enters the state where that makes it possible to operate in the Geiger mode again. With the increase of voltage of the signal S1, the generation section 20 causes voltage of the signal S2 to transition from the high level to the low level. In such a way, the generation section 20 may output the signal S2 serving as a pulse signal based on voltage of the signal S1, to the signal line 45.

The time from voltage drop between the electrodes of the light-receiving element 10 in response to the reception of a photon to voltage rise between the electrodes of the light-receiving element 10 in response to the recharge can be said as dead time in which the quenching and recharging are performed. In the example illustrated in FIG. 2, the dead time is a time period from a rising timing to a falling timing of the signal S2 serving as the pulse signal, that is, time corresponding to a high-level pulse width of the signal S2. When the dead time is long, there is a possibility that highly accurate photodetection is not performed. Therefore, by using the photodetection device 1 according to the present embodiment, it is possible to perform control in such a manner that the pulse width of the signal S2 is adjusted and the dead time becomes shortened. Next, the photodetection device 1 according to the present embodiment will be described more in detail.

The control section 110 of the photodetection device 1 includes a detection section 60, a signal determination section 70, a signal retaining section 80, and a pixel control section 90, and is configured to control the pixel P on the basis of the pulse width of the signal S2. In the present embodiment, the control section 110 is configured to control supply of electric current to the light-receiving element 10 on the basis of the pulse width of the signal S2. It is to be noted that the detection section 60, the signal determination section 70, the signal retaining section 80, and the pixel control section 90 may be provided for each of the plurality of pixels P, for example.

The detection section 60 is configured to detect the pulse width of the signal S2. The signal S2 is input to the detection section 60 via the signal line 45. For example, the detection section 60 calculates the pulse width of the signal S2 by counting a time period where the signal S2 becomes the high level. The detection section 60 measures the pulse width of the signal S2, generate a signal related to the pulse width of the signal S2 (referred to as pulse width signal), and outputs it.

The signal determination section 70 is configured to determine the magnitude of the pulse width of the signal S2. The signal determination section 70 receives the pulse width signal input from the detection section 60. The pulse width signal indicates the pulse width of the signal S2. In the example illustrated in FIG. 2, the signal determination section 70 includes a retaining section 71 and a comparison section 72, and determines the magnitude of the pulse width of the signal S2. As an example, the retaining section 71 includes a latch circuit, and the comparison section 72 includes a comparator circuit. The retaining section 71 is configured to retain a signal related to the pulse width. The retaining section 71 retains (stores) data related to the pulse width of the signal S2, for example, the pulse width signal indicating the magnitude of the pulse width of the signal S2.

The comparison section 72 is configured to compare the pulse width of the signal S2 with a reference value. For example, the comparison section 72 compares the pulse width signal detected by the detection section 60 with a reference signal serving as a comparison target. The signal determination section 70 generates a signal (code signal) indicating a value (code) based on a result of comparison made by the comparison section 72. It can also be said that, the signal determination section 70 determines a magnitude relationship between the reference signal and the pulse width of the signal S2.

For example, the signal retaining section 80 includes a latch circuit. The signal retaining section 80 is configured to retain a signal for controlling the pixel P. For example, the signal retaining section 80 is configured to retain a signal related to a result of determination made by the signal determination section 70. The signal retaining section 80 retains (stores) the code signal generated by the signal determination section 70. The code signal generated depending on the magnitude of the pulse width of the signal S2 is input to and retained by the signal retaining section 80.

The pixel control section 90 is configured to control the respective sections of the pixel P. In the example illustrated in FIG. 2, the pixel control section 90 is configured to control the supply section 30 of the pixel P and control supply of electric current to the light-receiving element 10. The pixel control section 90 generates the signal Sc for controlling the supply section 30 of the pixel P on the basis of the code signal, and outputs the signal Sc to the pixel P. The pixel control section 90 may control the supply of electric current to the light-receiving element 10 by controlling the signal Sc.

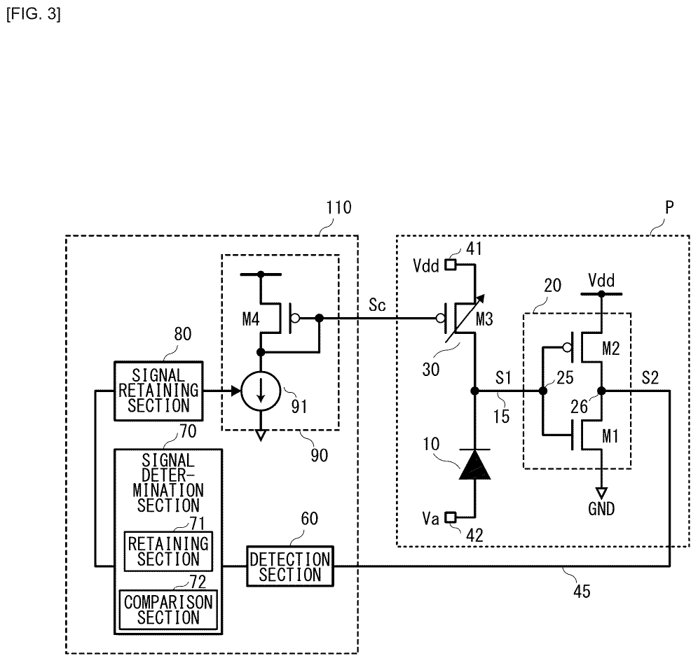

As an example, as illustrated in FIG. 3, the pixel control section 90 includes an electric current source 91 and a transistor M4. The electric current source 91 may generate electric current (reference current) corresponding to a value of a code signal retained in the signal retaining section 80 and supply it to the transistor M4. The transistor M4 is a PMOS transistor. The transistor M4 generates a signal Sc having voltage corresponding to the reference current from the electric current source 91 and supplies it to the supply section 30 of each pixel P. The pixel control section 90 makes it possible to change the signal level of the signal Sc depending on the code signal retained in the signal retaining section 80 and adjust electric current to be supplied from the supply section 30 to the light-receiving element 10.

As described above, the photodetection device 1 according to the present embodiment controls electric current to be supplied to the light-receiving element 10 in response to a code signal decided on the basis of the pulse width of a signal S2. The control section 110 makes it possible to change time it takes to perform the quenching and recharging and vary the pulse width of the signal S2 by controlling electric current to be supplied from the supply section 30. This makes it possible to adjust magnitude (current value) of recharge current and shorten the pulse width of the signal S2, that is, the dead time. Accordingly, the photodetection device 1 makes it possible to prevent decline in accuracy of photodetection and to perform photodetection with high accuracy even in a case where illuminance is high. This makes it possible to improve accuracy of ranging.

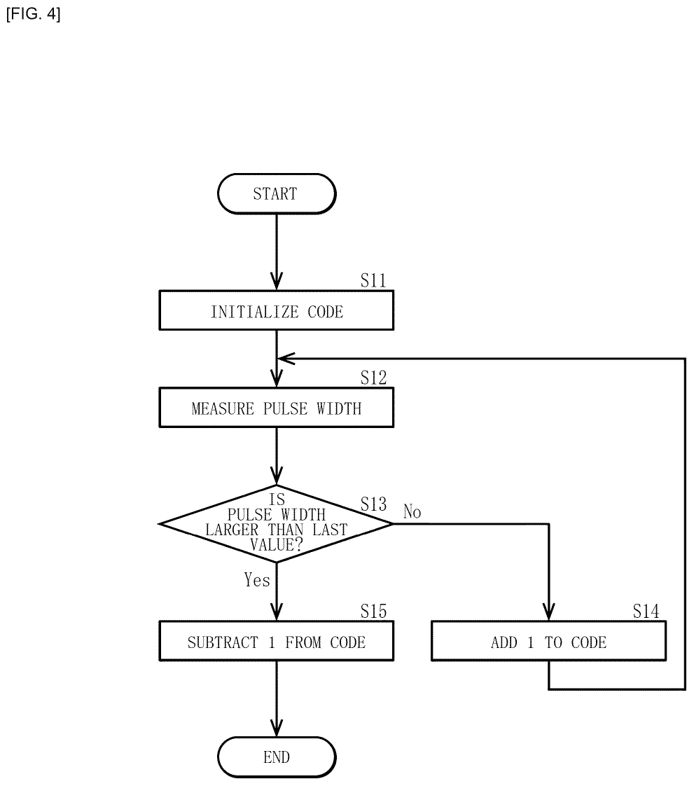

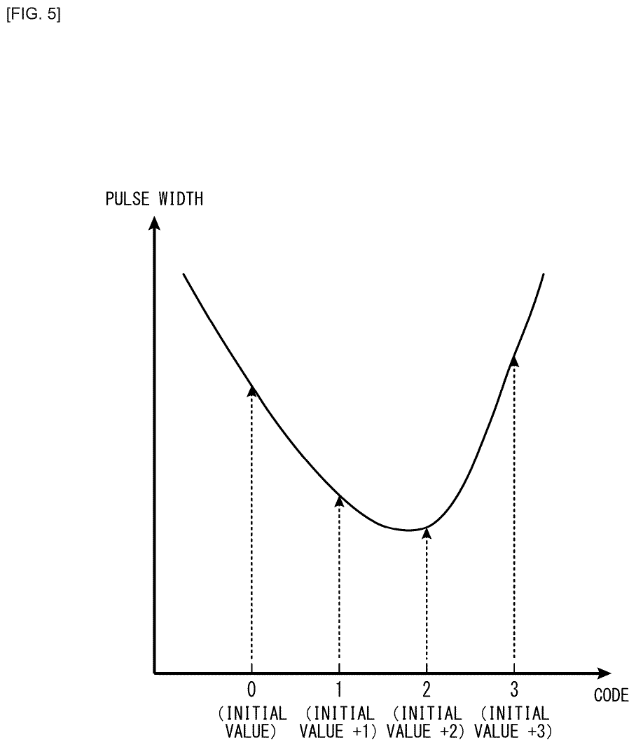

FIG. 4 is a flowchart illustrating an operation example of the photodetection device according to the first embodiment. FIG. 5 is a diagram for describing control over the pulse width by the photodetection device according to the first embodiment. In FIG. 5, the vertical axis represents pulse width of the signal S2, and the horizontal axis represents values of the code signal. With reference to FIG. 4 and FIG. 5, the operation example of the photodetection device 1 will be described.

In Step S11 in FIG. 4, the control section 110 of the photodetection device 1 initializes the signal retaining section 80. In this case, the control section 110 causes the signal retaining section 80 to retain a code signal indicating an initial value. The pixel control section 90 inputs a signal Sc to the supply section 30 of the pixel P. The signal Sc has voltage corresponding to the code signal having the initial value. The supply section 30 makes it possible to supply the light-receiving element 10 with electric current corresponding to the code signal of the initial value. It is to be noted that, in the example illustrated in FIG. 5, the initial value of the code signal is zero.

The light-receiving element 10 generates a signal S1 in response to reception of a photon. In a case where the supply section 30 makes it possible to supply the light-receiving element 10 with the electric current corresponding to the code signal of the initial value, the generation section 20 generates and outputs a signal S2 on the basis of the signal S1 generated by the light-receiving element 10. The signal S2 serves as a pulse signal.

In Step S12, the detection section 60 performs first measurement and detects the pulse width of the signal S2 output from the generation section 20. The retaining section 71 of the signal determination section 70 retains a pulse width signal indicating the magnitude of the pulse width of the signal S2 measured this time.

In Step S13, the signal determination section 70 determines the magnitude of the pulse width by comparing the pulse width signal measured in the current measurement with a pulse width signal that are measured in last measurement and retained in the retaining section 71. The signal determination section 70 determines whether or not the pulse width of the signal S2 detected this time is larger than the pulse width of the signal S2 detected last time. The process proceeds to Step S14 in a case where the result of determination in Step S13 is negative (“No” in Step S13). The process proceeds to Step S15 in a case where the result of determination in Step S13 is positive (“Yes” in Step S13). It is to be noted that, in a case of a very-first pulse width determination process, there is no previous pulse width signal and the process proceeds to Step S14.

In Step S14, the signal determination section 70 causes the signal retaining section 80 to retain a code signal indicating a value obtained by adding 1 to the initial value that is the value of the current code signal. This updates the code signal in the signal retaining section 80, and the signal retaining section 80 retains the code signal indicating (initial value+1). The pixel control section 90 inputs a signal Sc to the supply section 30. The signal Sc has voltage corresponding to the code signal having (initial value+1). In a case where the signal Sc corresponding to the code signal having (initial value+1) is input to the supply section 30, the supply section 30 makes it possible to supply the light-receiving element 10 with electric current that is larger than a case where a signal Sc corresponding to a code signal having the initial value is input. After Step S14, the process returns to Step S12.

In Step S12 subsequent to Step S14, the detection section 60 performs second measurement and detects pulse width of a signal S2 output from the pixel P in a case where the code signal has (initial value+1). As illustrated in FIG. 5, in a case where the code signal has (initial value+1), the signal S2 has smaller pulse width than the case where the code signal has the initial value. The retaining section 71 of the signal determination section 70 retains a pulse width signal indicating the pulse width measured this time.

In Step S13, the comparison section 72 of the signal determination section 70 refers to the pulse width signal retained in the retaining section 71, and compares the pulse width of the signal S2 obtained in the current measurement, that is, in a case where the code signal has (initial value+1), with pulse width of a signal S2 obtained in the last measurement, that is, in a case where the code signal has the initial value. On the basis of a result of the comparison made by the comparison section 72, the signal determination section 70 determines that the pulse width obtained in the current measurement is smaller than the pulse width obtained in the last measurement, and the process proceeds to Step S14.

In Step S14, the signal determination section 70 causes the signal retaining section 80 to retain a code signal indicating (initial value+2) obtained by adding 1 to (initial value+1) that is the value of the current code signal. The pixel control section 90 inputs a signal Sc to the supply section 30. The signal Sc has voltage corresponding to the code signal having (initial value+2). When the pixel control section 90 inputs the signal Sc corresponding to the code signal having (initial value+2) to the supply section 30, the supply section 30 makes it possible to supply the light-receiving element 10 with electric current that is larger than a case where a signal Sc corresponding to a code signal having (initial value+1) is input. After Step S14, the process returns to Step S12 again.

In Step S12 subsequent to Step S14, the detection section 60 performs third measurement and detects pulse width of a signal S2 output from the pixel P in a case where the code signal has (initial value+2). As illustrated in FIG. 5, in a case where the code signal has (initial value+2), the signal S2 has smaller pulse width than the case where the code signal has (initial value+1). The retaining section 71 retains a pulse width signal indicating the pulse width measured this time.

In Step S13, the comparison section 72 compares the pulse width of the signal S2 obtained in the current measurement, that is, in a case where the code signal has (initial value+2), with pulse width of a signal S2 obtained in the last measurement, that is, in a case where the code signal has (initial value+1). The signal determination section 70 determines that the pulse width obtained in the current measurement is smaller than the pulse width obtained in the last measurement, and the process proceeds to Step S14.

In Step S14, the signal determination section 70 causes the signal retaining section 80 to retain a code signal indicating (initial value+3) obtained by adding 1 to (initial value+2) that is the value of the current code signal. The pixel control section 90 inputs a signal Sc to the supply section 30. The signal Sc has voltage corresponding to the code signal having (initial value+3). When the signal Sc corresponding to the code signal having (initial value+3) is input to the supply section 30, the supply section 30 makes it possible to supply the light-receiving element 10 with electric current that is larger than a case where a signal Sc corresponding to a code signal having (initial value+2) is input. After Step S14, the process returns to Step S12 again.

In Step S12 subsequent to Step S14, the detection section 60 performs fourth measurement and detects pulse width of a signal S2 output from the pixel P in a case where the code signal has (initial value+3). As illustrated in FIG. 5, in a case where the code signal has (initial value+3), the signal S2 has larger pulse width than the case where the code signal has (initial value+2). The retaining section 71 retains a pulse width signal indicating the pulse width measured this time.

In Step S13, the signal determination section 70 determines that the pulse width of the signal S2 obtained in the current measurement, that is, in a case where the code signal has (initial value+3) is larger than the pulse width of a signal S2 obtained in the last measurement, that is, in a case where the code signal has (initial value+2). Then, the process proceeds to Step S15.

In Step S15, the signal determination section 70 causes the signal retaining section 80 to retain a code signal indicating (initial value+2) obtained by subtracting 1 from (initial value+3) that is the value of the current code signal. The signal Sc corresponding to the code signal having (initial value+2) is input to the supply section 30, and the supply section 30 makes it possible to supply the light-receiving element 10 with electric current corresponding to the code signal having (initial value+2). After Step S15, the photodetection device 1 ends the process illustrated in the flowchart in FIG. 4.

As described above, by repeating detection of the pulse width of a signal S2 while varying electric current from the supply section 30, it is possible to decide the value of the code signal indicating the signal S2 having the smallest pulse width. The photodetection device 1 makes it possible to shorten the pulse width of the signal S2 and the dead time by setting electric current from the supply section 30 on the basis of the decided code signal. This makes it possible to minimize the pulse width of the signal S2, and improve accuracy of photodetection.

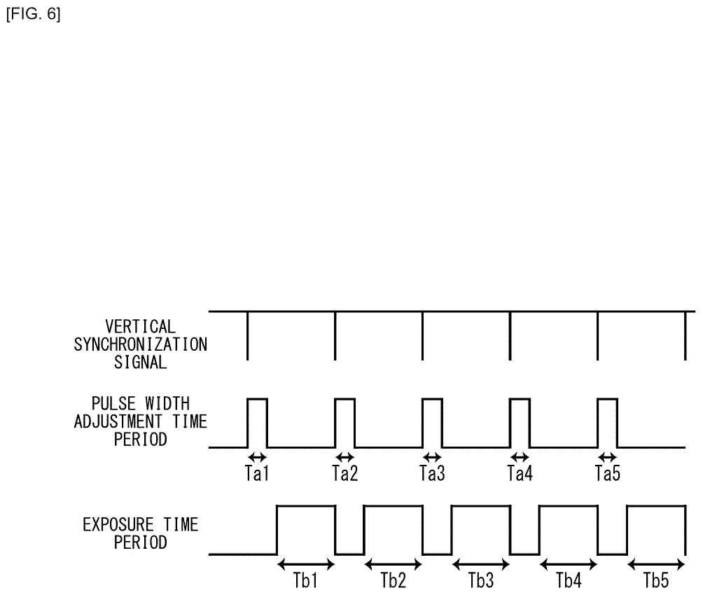

It is also possible for the photodetection device 1 to perform the process illustrated in the flowchart in FIG. 4 for each frame of a predetermined cycle, for example. FIG. 6 is a diagram for describing an example of timing of executing the process by the photodetection device according to the first embodiment. FIG. 6 schematically illustrates a vertical synchronization signal, pulse width adjustment time periods Ta1 to Ta5, and exposure time periods Tb1 to Tb5 on a same time axis. For example, the vertical synchronization signal is generated on the basis of a frame rate of imaging, and indicates a time interval of a single frame. The exposure time period of each frame is set on the basis of the vertical synchronization signal.

The control section 110 of the photodetection device 1 may perform the process illustrated in the flowchart in FIG. 4 in the pulse width adjustment time periods Ta1 to Ta5. As in the example illustrated in FIG. 6, the control section 110 may execute the above-described steps S11 to S15 before the exposure time period of each frame. It becomes possible to effectively suppress reduction in photodetection performance by adjusting the pulse width for each frame.

It is to be noted that the example of measuring the pulse width while changing the code by 1 has been described above. However, it is also possible to measure the pulse width while changing the code by 2. For example, detection of the pulse width of the signal S2 may be repeated while changing electric current from the supply section 30 by increasing the value of the code signal by 2.

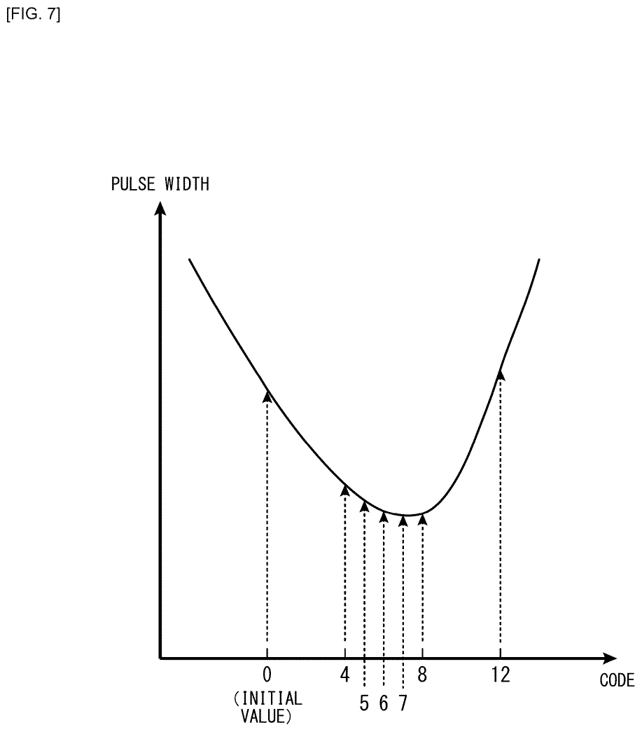

In addition, for example, as in an example illustrated in FIG. 7, it is also possible for the photodetection device 1 to set the value of the code signal to (initial value), (initial value+4), (initial value+8), (initial value+12) in this order and measure the pulse width. Alternatively, it is also possible for the photodetection device 1 to perform measurement while changing the code value in a large step (4 in FIG. 7), and then perform measurement while changing the code value in a small step (1 in FIG. 7). In the example illustrated in FIG. 7, it is possible to change the value of the code signal to (initial value+5), (initial value+6), and (initial value+7) in this order and adjust the pulse width of the signal S2.

### [Workings and Effects]

The photodetection device (photodetection device 1) according to the present embodiment includes: the light-receiving element (light-receiving element 10) configured to receive light and generate a signal; the generation section (generation section 20) configured to generate a first signal (signal S2) based on the signal generated by the light-receiving element; and the control section (control section 110, pixel control section 90) configured to control supply of electric current to the light-receiving element on the basis of pulse width of the first signal.

The photodetection device 1 according to the present embodiment controls supply of electric current to the light-receiving element 10 on the basis of the pulse width of the signal S2 generated in response to reception of a photon by the light-receiving element 10. This makes it possible to adjust the pulse width of the signal S2 and shorten the dead time. This makes it possible to provide the photodetection device 1 having high detection performance.

Next, modifications of the present disclosure will be described. Hereinafter, structural elements that are similar to the above-described embodiment will be denoted with the same reference signs as the above-described embodiment, and repeated description will be omitted appropriately.

### (1-1. First Modification)

In the above-described embodiment, the configuration example of the photodetection device 1 has been described. However, the configuration of the photodetection device 1 is not limited to the above-described examples. For example, the detection section 60 of the photodetection device 1 may be configured as in the following examples.

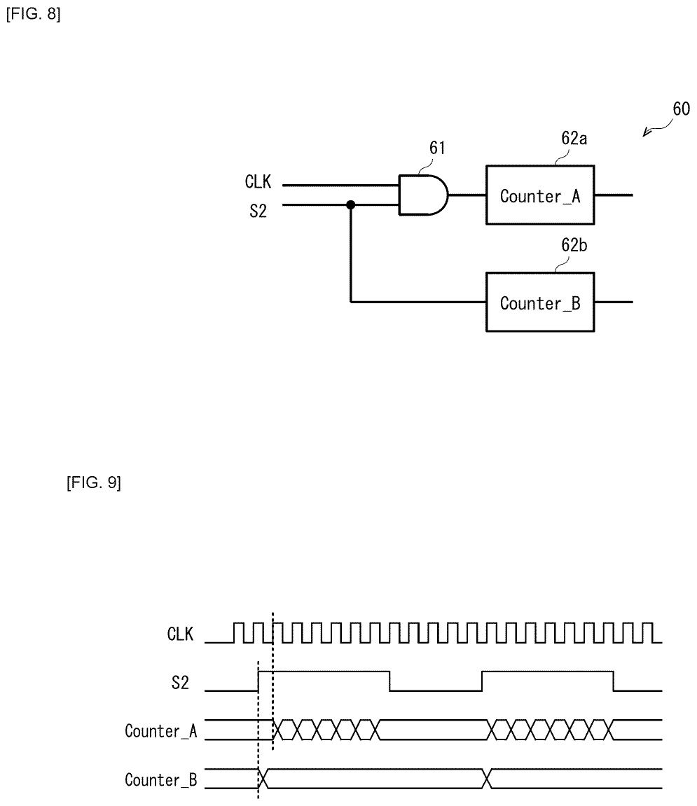

FIG. 8 is a diagram illustrating a configuration example of a detection section of a photodetection device according to a first modification. FIG. 9 is a timing diagram illustrating an operation example of the detection section of the photodetection device according to the first modification. A detection section 60 includes an AND circuit 61 and two counters 62 (first counter 62a and second counter 62b). The AND circuit 61 receives input of a clock signal CLK and the signal S2 from the generation section 20 of the pixel P.

The first counter 62a receives input of an output signal from the AND circuit 61. In the examples illustrated in FIG. 8 and FIG. 9, the first counter 62a counts the clock signal CLK on the basis of the output signal from the AND circuit 61 in a time period where the signal S2 becomes the high level. The first counter 62a counts the number of pulses of the clock signal CLK as a first count value in the time period where the signal S2 becomes the high level. Then the first counter 62a outputs a signal indicating the first count value. The second counter 62b receives input of the signal S2 from the pixel P. The second counter 62b counts the number of pulses of the signal S2 as a second count value and outputs a signal indicating the second count value.

The detection section 60 calculates the pulse width of the signal S2 on the basis of the first count value obtained by the first counter 62a, the second count value obtained by the second counter 62b, the cycle of the clock signal CLK, and the following expression (1).

$$Pulse Width of S2 = Cycle of CLK \times First Count Value / Second Count Value \qquad ( 1 )$$

By using the above-listed expression (1), it is possible to calculate an average value of the pulse widths of the signal S2. The detection section 60 may output the pulse width signal indicating the pulse width of the signal S2, as a result of detection.

### (1-2. Second Modification)

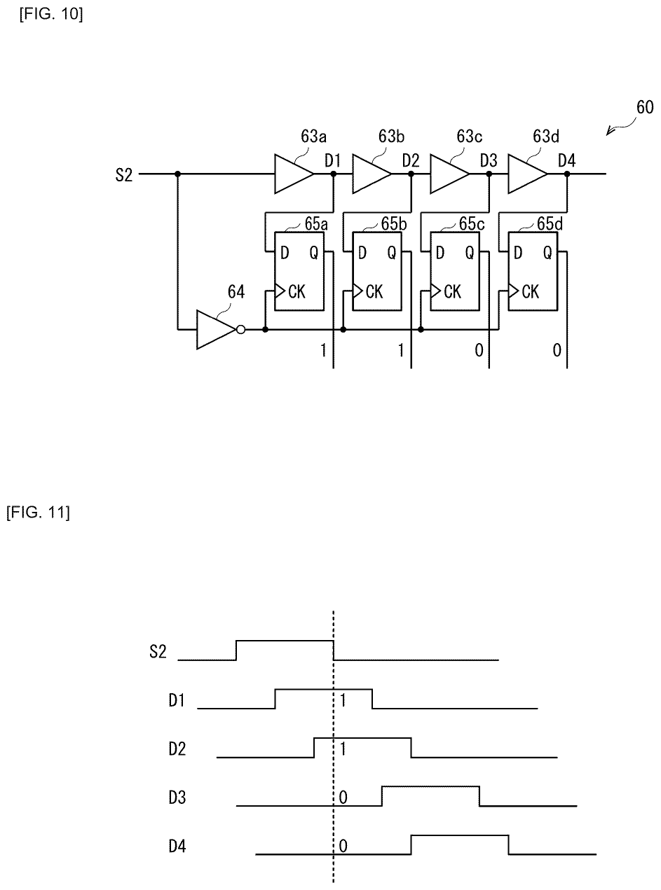

FIG. 10 is a diagram illustrating a configuration example of a detection section of a photodetection device according to a second modification. FIG. 11 is a timing diagram illustrating an operation example of the detection section of the photodetection device according to the second modification. A detection section 60 includes a plurality of DLY circuits (delay circuits) 63, an INV circuit (inverter) 64, and a plurality of FF circuits (flip-flops) 65. The DLY circuits (DLY circuits 63a to 63d) delays and outputs an input signal. As illustrated in FIG. 10 and FIG. 11, signals D1 to D4 are generated by sequentially delaying the signal S2 of the pixel P.

Each of the FF circuits (FF circuits 65a to 62d) is a D-FF circuit, for example. The INV circuit 64 outputs an inversion signal of the input signal S2. The INV circuit 64 inputs the inversion signal of the signal S2 to the FF circuits 65a to 65d as the clock signal. As in the examples illustrated in FIG. 10 and FIG. 11, the FF circuits 65a to 65d retain values of input signals S1 to D4 on the basis of a falling timing of the signal S2. The FF circuits 65a to 65d retain different values depending on a time period where the signal S2 becomes the high level. The detection section 6 makes it possible to generate a pulse width signal indicating the pulse width of the signal S2 by using the signals retained in the respective FF circuits 65.

### (1-3. Third Modification)

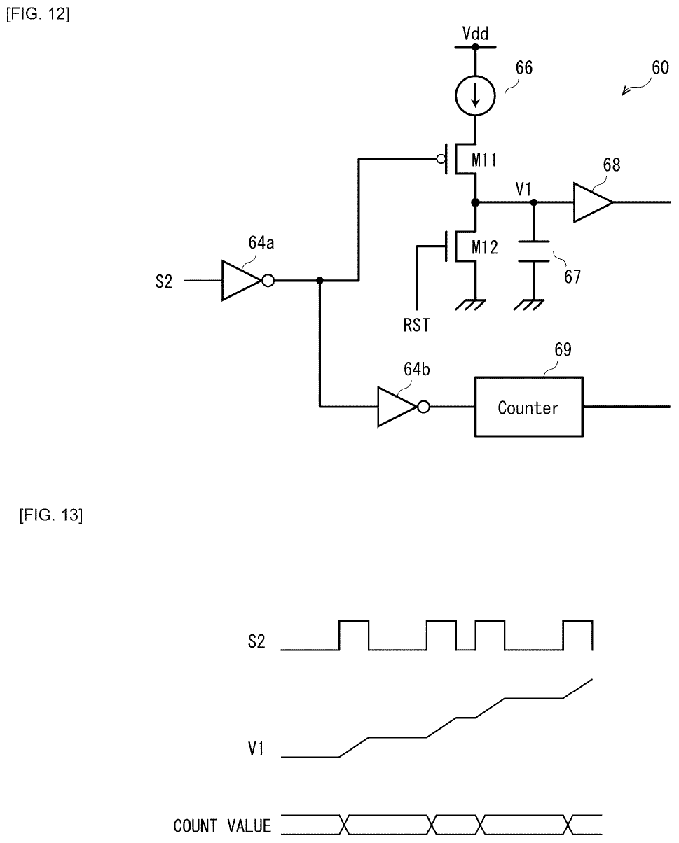

FIG. 12 is a diagram illustrating a configuration example of a detection section of a photodetection device according to a third modification. FIG. 13 is a timing diagram illustrating an operation example of the detection section of the photodetection device according to the third modification. A detection section 60 includes INV circuits 64a and 64b, transistors M11 and M12, an electric current source 66, a capacitive element 67, an output section 68, and a counter 69. The transistor M11 is a PMOS transistor, while the transistor M12 is an NMOS transistor.

The transistor M11 may supply electric current from the electric current source 66 to the capacitive element 67 under the control of an inversion signal of a signal S2 input from the INV circuit 64a. For example, the capacitive element 67 is an MOS capacitor, an MIM capacitor, or the like, and has a capacitance value Co. In a time period where the signal S2 becomes the high level, the transistor M11 enters an ON state and the capacitive element 67 is charged by electric current Io of the electric current source 66, as illustrated in FIG. 13. For example, the output section 68 is a buffer circuit, and outputs a signal corresponding to voltage V1 of the capacitive element 67. The transistor M12 may reset the voltage V1 of the capacitive element 67 when entering the ON state under the control of a signal RST.

As illustrated in FIG. 13, the counter 69 counts the number of pulses of the signal S2 as a count value on the basis of a signal input via the INV circuits 64a and 64b. The counter 69 outputs a signal indicating the count value. The detection section 60 calculates the pulse width of the signal S2 on the basis of the output signal from the output section 68, the count value obtained by the counter 69, and the following expression (2).

$$Pulse Width of S 2 = Co \times V 1 / ( Io \times Count Value ) \qquad ( 2 )$$

The detection section 60 may find the pulse width of the signal S2 by using the above-listed expression (2) and may output a pulse width signal indicating the pulse width of the signal S2.

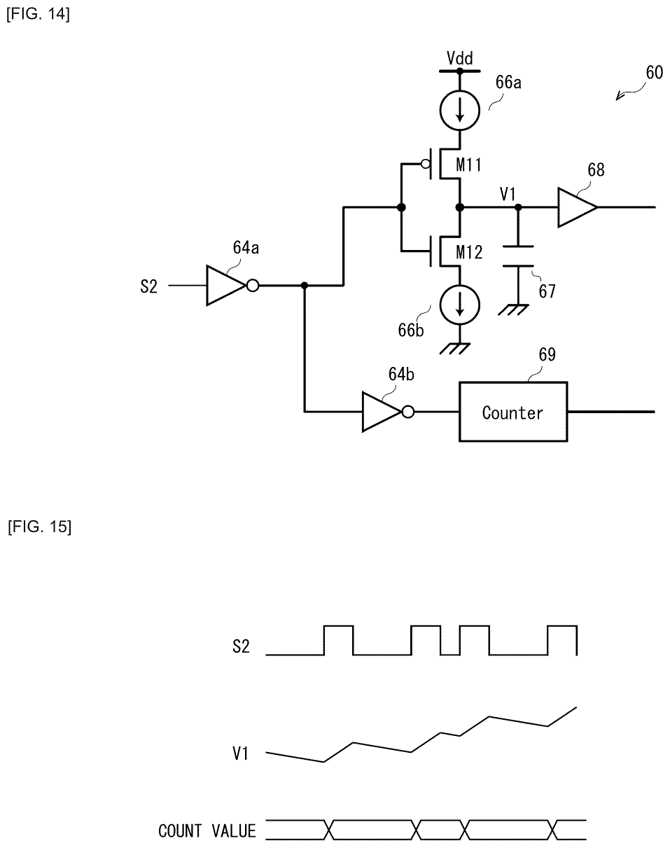

FIG. 14 is a diagram illustrating another configuration example of the detection section of the photodetection device according to the third modification. FIG. 15 is a timing diagram illustrating another operation example of the detection section of the photodetection device according to the third modification. In the example illustrated in FIG. 14, a detection section 60 includes an electric current source 66a coupled to the transistor M11 and an electric current source 66b coupled to the transistor M12.

In a case where the signal S2 becomes a high level, the transistor M11 enters the ON state and the capacitive element 67 is charged by electric current of the electric current source 66a in a way similar to the above-described example. In a case where the signal S2 becomes a low level, the transistor M12 enters the ON state and the capacitive element 67 is discharged by electric current of the electric current source 66b. This allows the voltage V1 of the capacitive element 67 to vary depending on the signal level of the signal S2, as in the example illustrated in FIG. 15. The voltage V1 of the capacitive element 67 is a value corresponding to a duty cycle, that is, a ratio of time when the signal S2 becomes the high level. The voltage V1 tends to get higher when the duty cycle increases, and the detection section 6 may estimate the duty cycle of the signal S2 on the basis of the voltage V1.

The detection section 60 calculates the pulse width of the signal S2 on the basis of exposure time in measurement, the duty cycle of the signal S2, and the following expression (3).

$$Pulse Width of S 2 = Exposure Time \times Duty Cycle / Count Value \qquad ( 3 )$$

The detection section 60 may find the pulse width of the signal S2 and output a pulse width signal indicating the pulse width of the signal S2.

### (1-4. Fourth Modification)

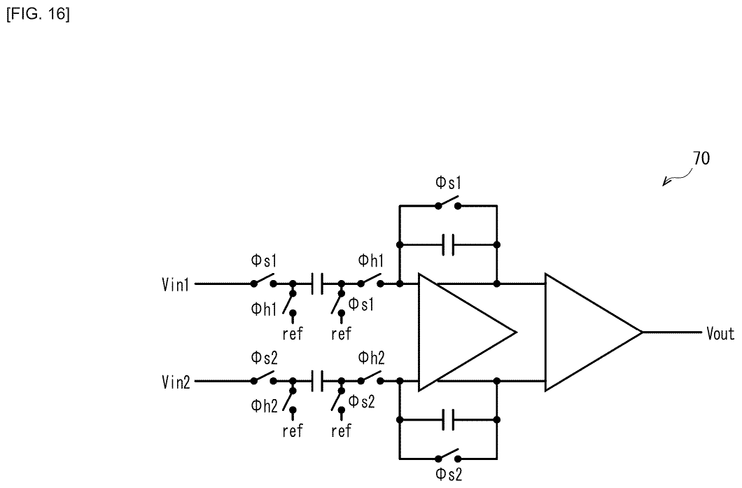

FIG. 16 is a diagram illustrating a configuration example of a signal determination section of a photodetection device according to a fourth modification. As in the example illustrated in FIG. 16, the signal determination section 70 of the photodetection device 1 may be implemented by an amplifier circuit. For example, the signal determination section 70 receives input of a signal S2 obtained in current measurement as a first input signal Vin1, and input of a signal S2 obtained in last measurement as a second input signal Vin2. The signal determination section 70 may output an output signal Vout having voltage depending on a difference between the first input signal Vin1 and the second input signal Vin2. The signal determination section 70 may generate and output a code signal based on a result of comparison between the pulse widths of the signal S2 in response to the output signal Vout.

### (1-5. Fifth Modification)

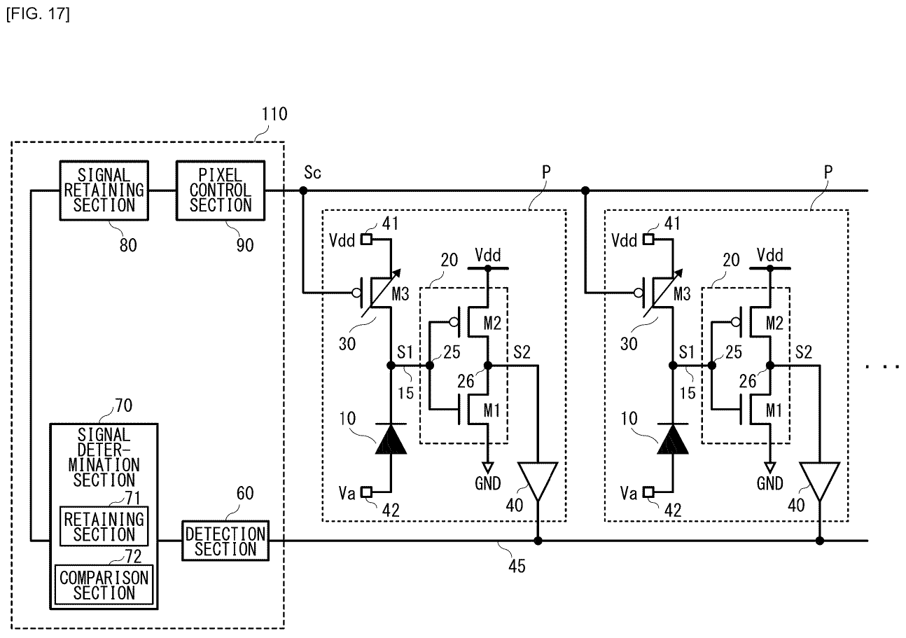

FIG. 17 is a diagram illustrating a configuration example of pixels and a control section of a photodetection device according to a fifth modification. In the example illustrated in FIG. 17, a set of the detection section 60, the signal determination section 70, the signal retaining section 80, and the pixel control section 90 is provided for each pixel row including a plurality of pixels P arranged in a horizontal direction (row direction) in the pixel section 100 (see FIG. 1). It can also be said that the respective pixels P in the pixel row share the detection section 60, the signal determination section 70, and the like.

The signal S2 is input from an output section 40 of each pixel P to the detection section 60 via the signal line 45. For example, the output section 40 is a buffer circuit. The pixel control section 90 is provided in common for the respective pixels P in the pixel row. In the example illustrated in FIG. 17, the pixel control section 90 may be electrically coupled to and control the supply sections 30 of the respective pixels P in the pixel row. It is to be noted that the set of the detection section 60, the signal determination section 70, the signal retaining section 80, and the pixel control section 90 may be provided for each pixel column including a plurality of pixels P arranged in a vertical direction (column direction) in the pixel section 100.

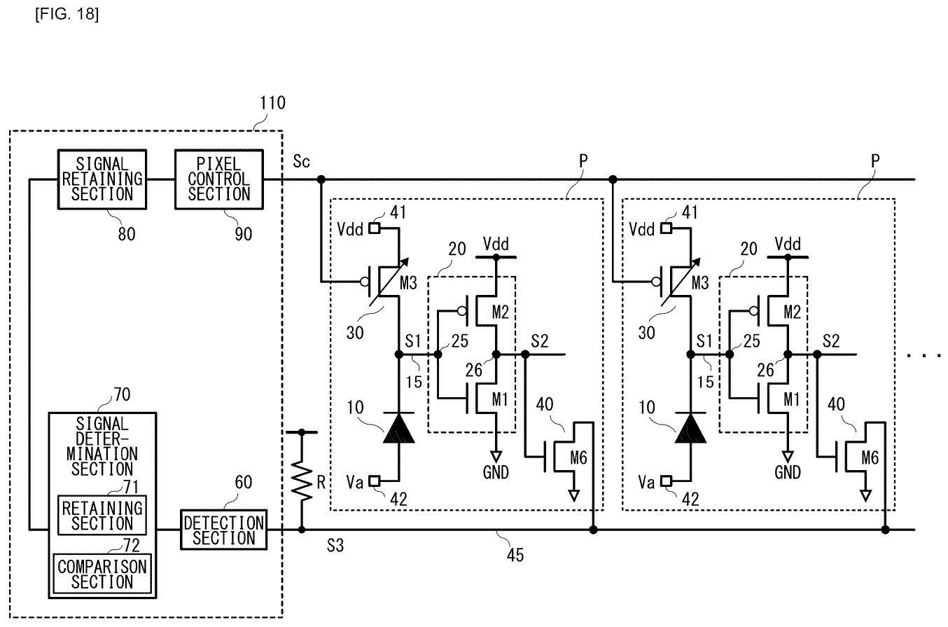

It is to be noted that, as illustrated in FIG. 18, the output section 40 of the pixel P may be implemented by an open-drain transistor M6. In the example illustrated in FIG. 18, the transistor M6 of the output section 40 is electrically coupled to the signal line 45 and a resistance element R, and outputs a signal S3 based on the signal S2 to the detection section 60. The detection section 60 may calculate the pulse width of the signal S2 by using the signal S3 output from the transistor M6 of the output section 40.

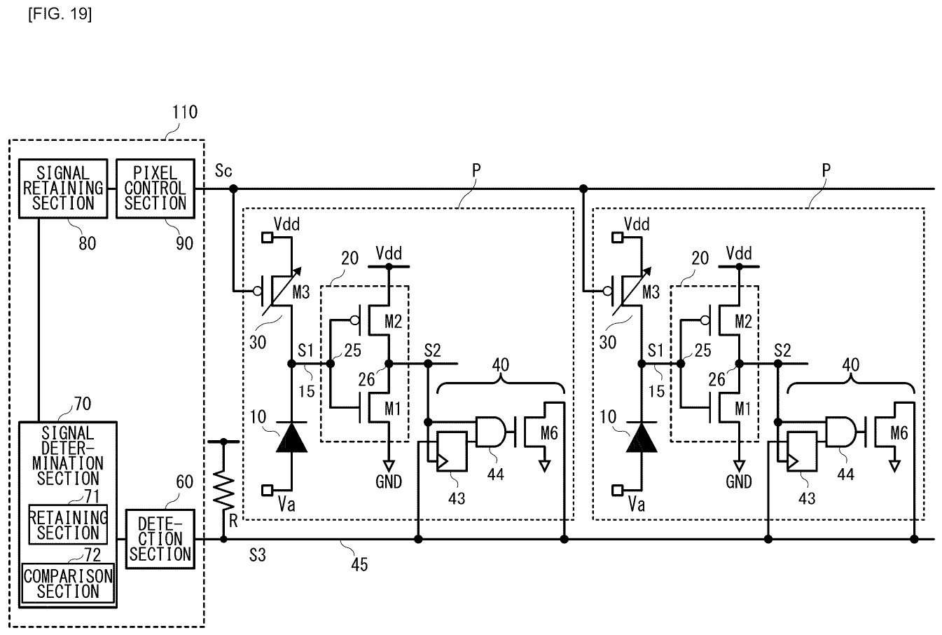

The output section 40 of the pixel P may switch whether or not to output the signal S3 depending on the voltage level of the signal line 45. In an example illustrated in FIG. 19, the output section 40 includes an FF circuit 43 and an AND circuit 44. The output section 40 outputs the signal S3 to the signal line 45 in a case where the signal line 45 has high-level voltage, that is, in a case where another pixel P does not output a low-level signal to the signal line 45. This makes it possible to suppress erroneous detection of the pulse width in the detection section 60.

### (1-6. Sixth Modification)

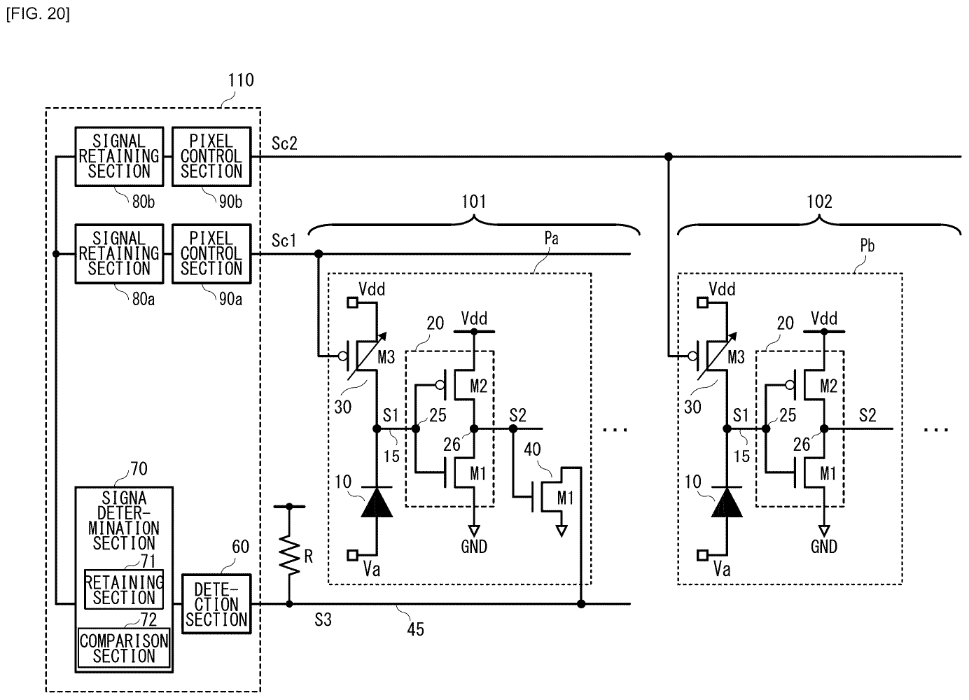

FIG. 20 is a diagram illustrating another configuration example of pixels and a control section of a photodetection device according to a sixth modification. In the example illustrated in FIG. 20, a pixel section 100 of a photodetection device 1 includes a region (corrective pixel region) 101 and a region (non-corrective pixel region) 102. In the region (corrective pixel region) 101, pixels Pa for pulse width detection (referred to as corrective pixels) are arranged. In the region (non-corrective pixel region) 102, other pixels (referred to as non-corrective pixels) Pb are arranged.

The detection section 60 of the control section 110 receives input of a signal S3 based on a signal S2 generated by the corrective pixel Pa in the corrective pixel region 101. The detection section 60 calculates the pulse width of the signal S2 of the corrective pixel Pa by using the signal S3. The control section 110 may generate a code signal corresponding to the pulse width of the signal S2 of the corrective pixel Pa, and may control electric current of the respective supply sections 30 of the corrective pixel Pa and the non-corrective pixel Pb on the basis of the generated code signal. This makes it possible to detect and correct the pulse width of the signal S2 by using the corrective pixel Pa in the corrective pixel region 101 while imaging and ranging by using the non-corrective pixel Pb in the non-corrective pixel region 102.

It is to be noted that, in the example illustrated in FIG. 20, a signal retaining section 80a and a pixel control section 90a are provided for the plurality of corrective pixels Pa in the corrective pixel region 101. In addition, a signal retaining section 80b and a pixel control section 90b are provided for the plurality of non-corrective pixels Pb in the non-corrective pixel region 102. The pixel control section 90a generates a signal Sc1 for controlling the corrective pixels Pa on the basis of a code signal retained in the signal retaining section 80a, and outputs the generated signal Sc1 to the corrective pixels Pa. The pixel control section 90b generates a signal Sc2 for controlling the non-corrective pixels Pb on the basis of a code signal retained in the signal retaining section 80b, and outputs the generated signal Sc2 to the non-corrective pixels Pb. The control section 110 makes it possible to control the corrective pixels Pa and the non-corrective pixels Pb by using the pixel control section 90a and the pixel control section 90b.

### (1-7. Seventh Modification)

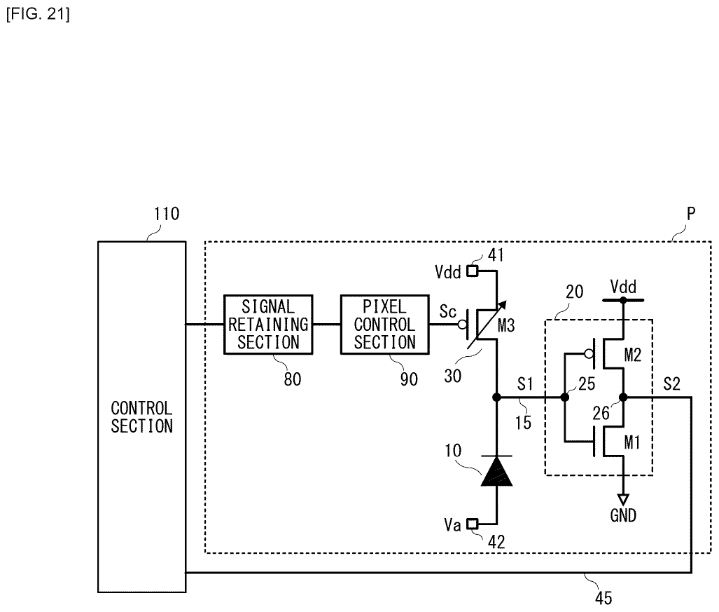

FIG. 21 is a diagram illustrating a configuration example of a pixel and a control section of a photodetection device according to a seventh modification. In the example illustrated in FIG. 21, each pixel is provided with the signal retaining section 80 and the pixel control section 90. In this case, the signal retaining section 80 of each pixel P makes it possible to retain a code signal that is different for each pixel P. The pixel control section 90 of the pixel P controls the supply section 30 on the basis of the code signal retained in the signal retaining section 80, and controls supply of electric current to the light-receiving element 10. The Seventh modification makes it possible to individually control electric current to the light-receiving element 10 of each pixel P, and adjust the pulse width of the signal S2 of each pixel P with high accuracy. This makes it possible to suppress variation in the pulse width of the signal S2 between the respective pixels P.

### (1-8. Eighth Modification)

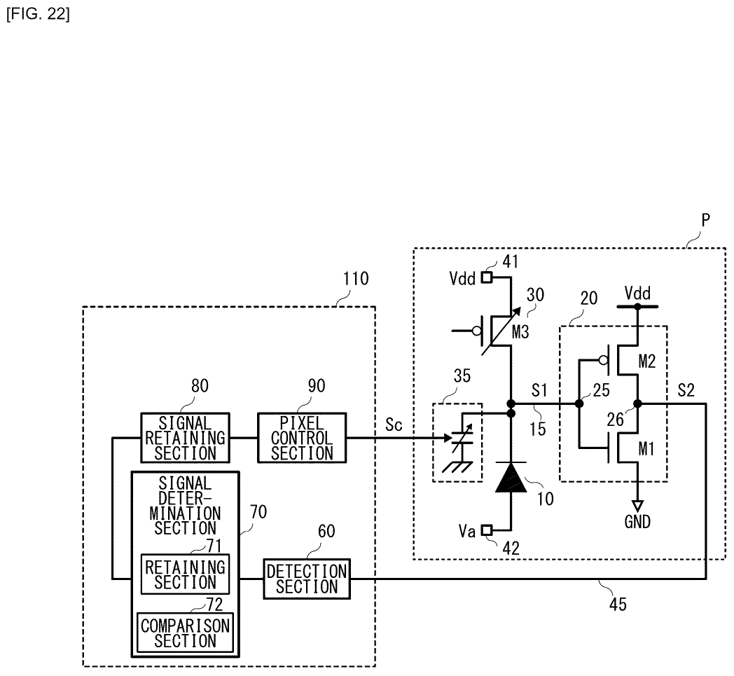

FIG. 22 is a diagram illustrating a configuration example of a pixel and a control section of a photodetection device according to an eighth modification. As illustrated in FIG. 22, a pixel P includes a capacitor section 35. The capacitor section 35 is configured to change a capacitance value under the control of the pixel control section 90. The capacitor section 35 is a variable capacitor section, and is electrically coupled to the supply section 30 and the cathode of the light-receiving element 10. The capacitor section 35 is coupled to a node 15 that couples the supply section 30 to the light-receiving element 10.

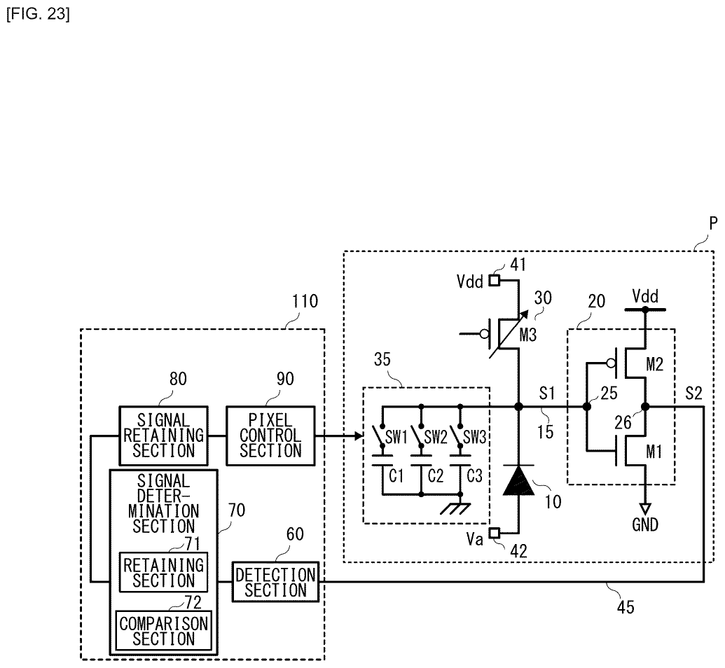

For example, as illustrated in FIG. 23, the capacitor section 35 includes a plurality of switches (switches SW1 to SW3 in FIG. 23) and a plurality of capacitive elements (capacitive elements C1 to C3 in FIG. 23). The switches SW1 to SW3 are implemented by transistors. The capacitive elements C1 to C3 are implemented by MOS capacitors, MIM capacitors, or the like.

One of electrodes of the capacitive element C1 is coupled to the node 15 via the switch SW1, while another electrode of the capacitive element C1 is coupled to an earthing wire (ground wire). One of electrodes of the capacitive element C2 is coupled to the node 15 via the switch SW2, while another electrode of the capacitive element C2 is coupled to the earthing wire. One of electrodes of the capacitive element C3 is coupled to the node 15 via the switch SW3, while another electrode of the capacitive element C3 is coupled to the earthing wire.

The switch SW1 electrically couples or decouples the node 15 to/from the capacitive element C1. The switch SW2 electrically couples or decouples the node 15 to/from the capacitive element C2. The switch SW3 electrically couples or decouples the node 15 to/from the capacitive element C3. The pixel control section 90 supplies signals to the switches SW1 to SW3 and performs control in such a manner that the respective switches are turned on/off. The pixel control section 90 supplies the switches SW1 to SW3 with signals for controlling the switches SW1 to SW3 on the basis of the code signal retained in the signal retaining section 80, and switches connection states of the capacitive elements C1 to C3.

By chancing the capacitance value of the capacitor section 35 to be coupled to the node 15, it is possible for the control section 110 to adjust an amount of change (slope) of voltage of the signal S1 and finely adjust the pulse width of the signal S2. The control section 110 makes it possible to adjust the pulse width of the signal S2 by generating a code signal depending on the magnitude of the pulse width of the signal S2 and performing control in such a manner that the respective switches of the capacitor section 35 are turned on/off in response to the generated code signal. The photodetection device 1 makes it possible to adjust the capacitance value of the capacitor section 35 to be applied to the node 15 while using the pulse width of the signal S2 as the reference value, and prevent decline in accuracy of photodetection.

It is to be noted that the capacitor section 35 may be implemented by a variable capacitive element (varactor). It is also possible for the control section 110 to control magnitude of the anode voltage Va to be supplied to the light-receiving element 10, on the basis of the code signal generated depending on the magnitude of the pulse width of the signal S2.

### (1-9. Ninth Modification)

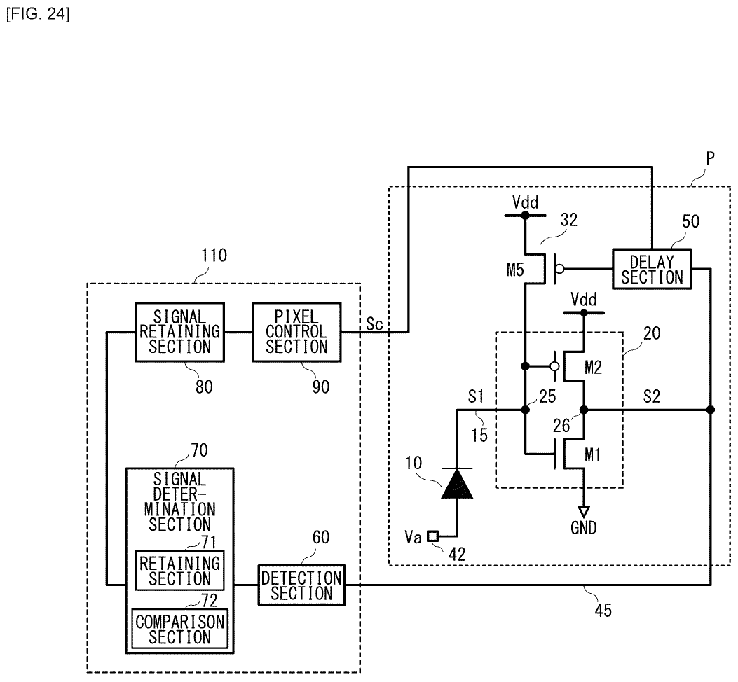

FIG. 24 is a diagram illustrating a configuration example of a pixel and a control section of a photodetection device according to a ninth modification. As illustrated in FIG. 24, a pixel P according to the ninth modification includes a delay section 50 and a switch 32. The delay section 50 is configured to delay and output an input signal. The delay section 50 receives input of a signal S2 generated by the generation section 20 in response to reception of a photon. The delay section 50 may be a DLY circuit (delay circuit) and may output a signal obtained by delaying the signal S2 to the switch 32.

The switch 32 is configured to electrically couple the light-receiving element 10 to the electric power source line on the basis of the signal S2. In the example illustrated in FIG. 4, the switch 32 receives input of the signal obtained by delaying the signal S2 from the delay section 50. In response to the signal S2, the switch 32 electrically couples or decouples the node 15 to/from the electric power source line that is given the power source voltage Vdd. The switch 32 can also be said as a supply section configured to supply electric current and voltage to the light-receiving element 10. The control is performed in such a manner that the switch 32 is turned on/off in response to the signal S2, and the quenching and recharging are performed on the light-receiving element 10.

In the example illustrated in FIG. 24, the switch 32 is implemented by a transistor M5. For example, the transistor M5 is a PMOS transistor. One of source or drain of the transistor M5 is coupled to the cathode of the light-receiving element 10. The other of source or drain of the transistor M5 is coupled to the electric power source line supplied with the power source voltage Vdd.

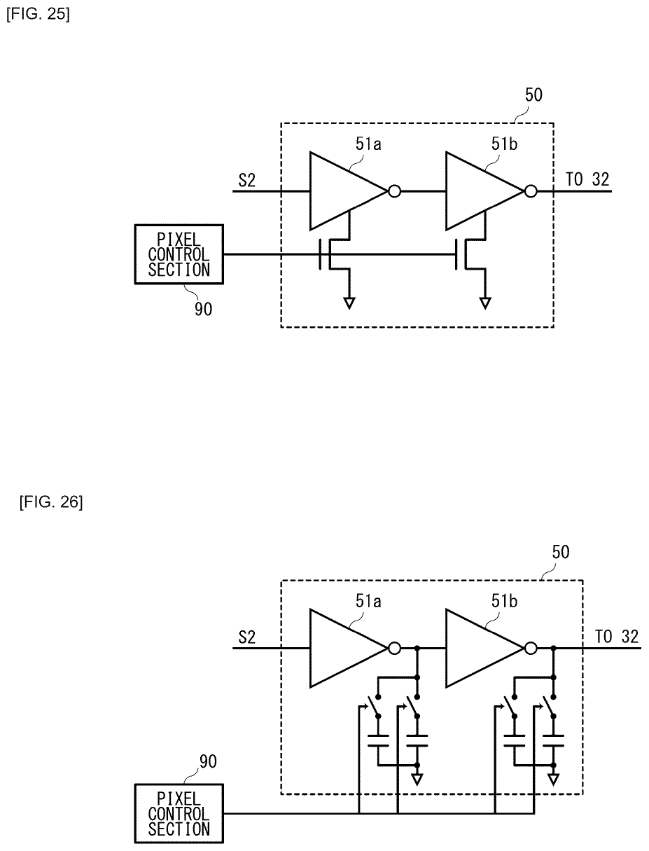

The delay section 50 is configured to change an amount of delay under the control of the pixel control section 90. For example, as illustrated in FIG. 25, the delay section 50 may be implemented by a plurality of INV circuits (INV circuits 51a and 51b in FIG. 25). As schematically illustrated in FIG. 25, the pixel control section 90 may control the amount of delay in the delay section 50 by controlling electric current flowing through the INV circuits. Alternatively, for example, as illustrated in FIG. 26, the delay section 50 may include a plurality of INV circuits and capacitor sections. In the example illustrated in FIG. 26, the pixel control section 90 may control the amount if delay in the delay section 50 by controlling capacitance values of the capacitor sections coupled to the INV circuits in the delay section 50.

In the ninth modification, the control section 110 generates a code signal depending on the magnitude of the pulse width of the signal S2 and controls the amount of delay in the delay section 50 in response to the generated code signal. By changing the amount of delay in the delay section 50, the control section 110 adjusts ON/OFF timings of the switch 32 and controls supply of electric current and voltage to the light-receiving element 10. This allows the photodetection device 1 to adjust the pulse width of the signal S2, and improve accuracy of photodetection.

### (1-10. Tenth Modification)

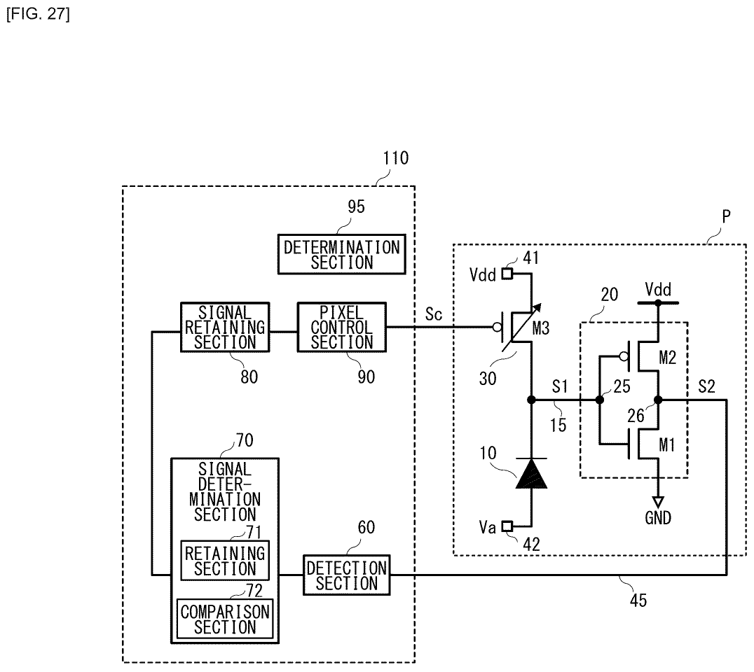

FIG. 27 is a diagram illustrating a configuration example of a pixel and a control section of a photodetection device according to a tenth modification. As illustrated in FIG. 27, the control section 110 of the photodetection device 1 includes a determination section 95. The determination section 95 is configured to determine whether or not to control the pixel P on the basis of the pulse width of the signal S2. As an example, the determination section 95 determines from illuminance of incident light, whether or not to control the pulse width of the signal S2.

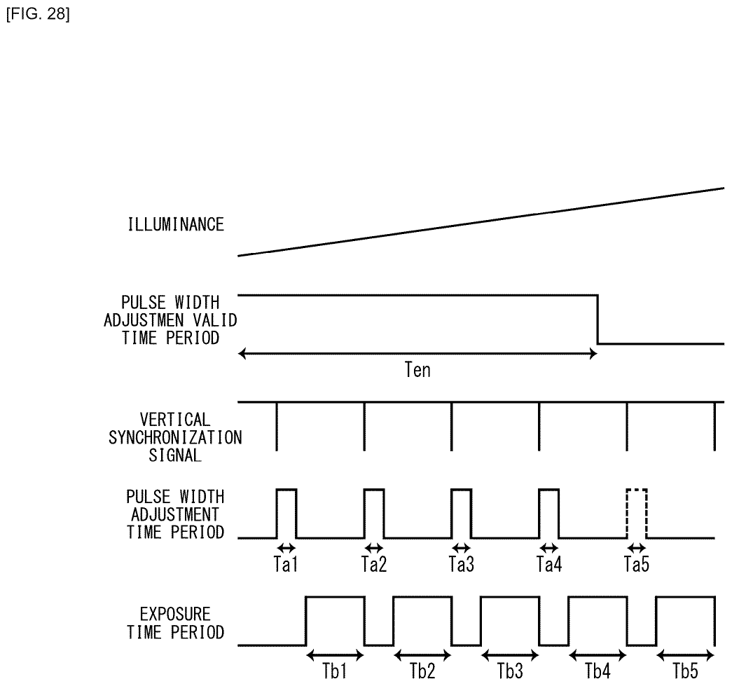

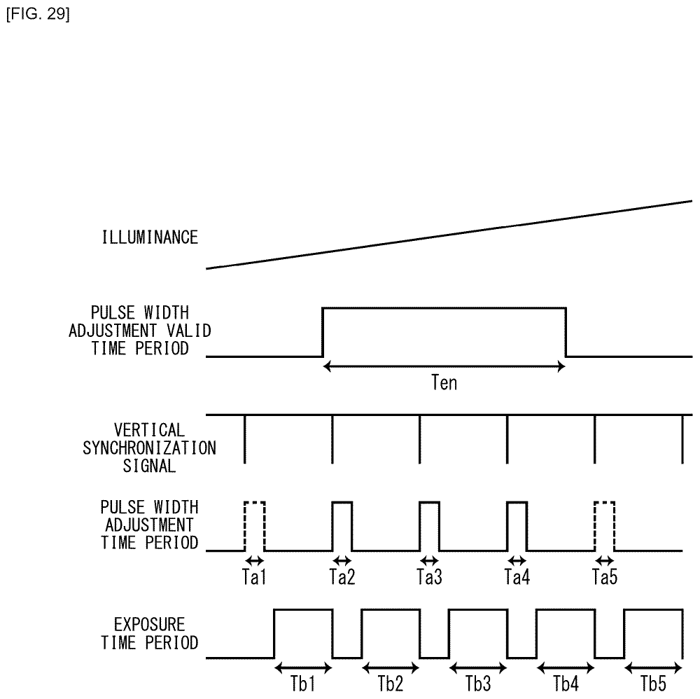

FIG. 28 and FIG. 29 are diagrams for describing examples of timing of executing a process by the photodetection device according to the tenth modification. FIG. 28 and FIG. 29 schematically illustrates illuminance of incident light, a pulse width adjustment valid time period Ten, a vertical synchronization signal, pulse width adjustment time periods Ta1 to Ta5, and exposure time periods Tb1 to Tb5 on a same time axis.

The determination section 95 determines whether or not to allow control over the pulse width of the signal S2 (control over electric current of the supply section 30, control over the capacitance value of the capacitor section 35, and the like as described above) depending on illuminance of incident light detected by an illuminance sensor. The determination section 95 sets the pulse width adjustment valid time period Ten indicating a time period where it is possible to adjust the pulse width, on the basis of a result of the determination. In the pulse width adjustment valid time period Ten, the control section 110 may adjust the pulse width of the signal S2 by performing the process illustrated in the flowchart in FIG. 4, for example. It is to be noted that the illuminance sensor (illuminometer) may be provided inside or outside the photodetection device 1.

As illustrated in FIG. 28, for example, the determination section 95 may set the pulse width adjustment valid time period Ten to a time period where incident light has illuminance that is less than a predetermined threshold. Alternatively, for example, as illustrated in FIG. 29, the determination section 95 may set the pulse width adjustment valid time period Ten to a time period where incident light has illuminance that is within a predetermined range. It is to be noted that, it is also possible for the determination section 95 to set the pulse width adjustment valid time period Ten to a time period where a measurement target is irradiated with light (such as laser light). In the tenth modification, it is possible to prevent erroneous determination of the pulse width in a case of high illuminance or low illuminance, and prevent deterioration in detection performance of the photodetection device 1.

### 2. Second Embodiment

Next, a second embodiment of the present disclosure will be described. Hereinafter, structural elements that are similar to the above-described embodiment will be denoted with the same reference signs as the above-described embodiment, and repeated description will be omitted appropriately.

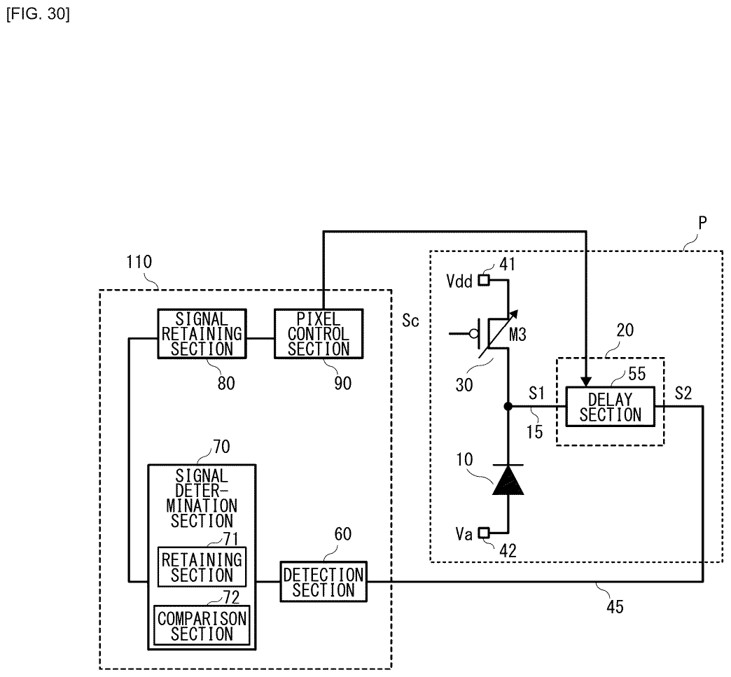

FIG. 30 is a diagram illustrating a configuration example of a pixel and a control section of a photodetection device according to a second embodiment. As illustrated in FIG. 30, a generation section 20 of the pixel P according to the present embodiment includes a delay section 55. The delay section 55 is a DLY circuit (delay circuit). The delay section 55 of the generation section 20 receives input of a signal S1 generated by the light-receiving element 10 in response to reception of a photon. The generation section 20 may output a signal S2 delayed by the delay section 55.

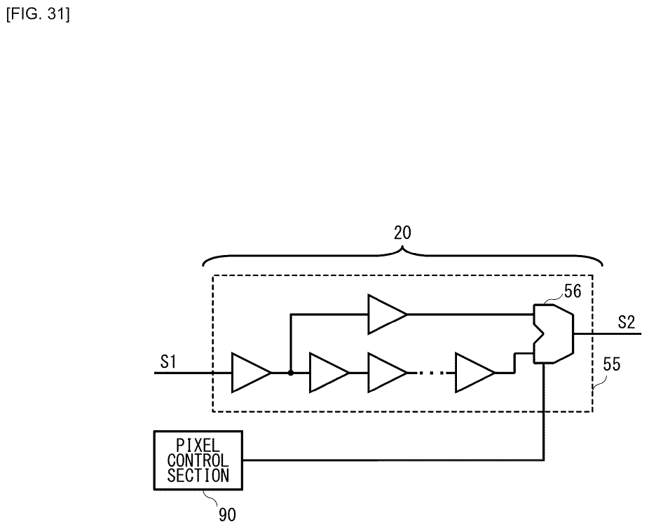

The delay section 55 is configured to change an amount of delay under the control of the pixel control section 90. For example, as illustrated in FIG. 31, the delay section 50 includes a plurality of buffer circuits or INV circuits and a switch circuit 56. The delay section 50 has a path with a small amount of delay and a path with a large amount of delay. For example, the switch circuit 56 is implemented by a multiplexer circuit. The pixel control section 90 may change the amount of delay in the delay section 55 by switching a signal path via the switch circuit 56. It is to be noted that the delay section 55 may be implemented by a capacitor section that makes it possible to change the amount of delay.

The control section 110 of the photodetection device 1 generates a code signal depending on the magnitude of the pulse width of the signal S2 and controls the amount of delay in the delay section 55 in response to the generated code signal. By chancing the amount of delay in the delay section 55, it is possible for the control section 110 to adjust the pulse width of the signal S2. This makes it possible to shorten the pulse width of the signal S2 and the dead time. This makes it possible to improve accuracy of photodetection.

### [Workings and Effects]

The photodetection device (photodetection device 1) according to the present embodiment includes: the light-receiving element (light-receiving element 10) configured to receive light and generate a signal; the generation section (generation section 20) configured to generate a first signal (signal S2) based on the signal generated by the light-receiving element; and the control section (control section 110, pixel control section 90) configured to control the generation section on the basis of pulse width of the first signal.

The photodetection device 1 according to the present embodiment controls the generation section 20 on the basis of the pulse width of the signal S2 generated in response to reception of a photon by the light-receiving element 10, and controls the amount of delay in the generation section 20. This makes it possible to adjust the pulse width of the signal S2 and shorten the dead time. This makes it possible to provide the photodetection device 1 having high detection performance.

### 3. Usage Example

For example, as will be described below, it is possible to apply the above-described photodetection devices 1 to various cases of sensing light such as visible light, infrared light, ultraviolet light, and X-ray.
A device shooting an image provided for viewing, such as a digital camera or portable device having a camera function.
A device provided for traffic, such as an in-vehicle sensor shooting the front side, the rear side, the circumference, the inside, or the like of the automobile, a monitoring camera monitoring a running vehicle or a road, and a ranging sensor measuring a distance between vehicles or the like, for a safety operation such as automatic stop, the recognition of the state of a driver, and the like.
A device provided for a home electrical appliance, such as a TV, a refrigerator, and an air conditioner, to shoot the gesture of the user, and to perform a device operation according to the gesture.
A device provided for a medical care or a health care, such as an endoscope or a device performing angiography by receiving infrared light.
A device provided for security, such as a monitoring camera for anti-crime and a camera for personal authentication.
A device provided for a beauty care, such as a skin measuring machine shooting the skin and a microscope shooting the scalp.
A device provided for sport, such as an action camera or a wearable camera for sport.
A device provided for agriculture, such as a camera monitoring the state of the cultivation or the crop.

### 4. Application Example

### (Example of Application to Mobile Object)

The technology according to the present disclosure (present technology) is applicable to various products. For example, the technology according to the present disclosure may be implemented as a device that is installed on any kind of mobile objects including vehicles, electric vehicles, hybrid electric vehicles, motorcycles, bicycles, personal mobilities, airplanes, drones, ships, robots, and the like.

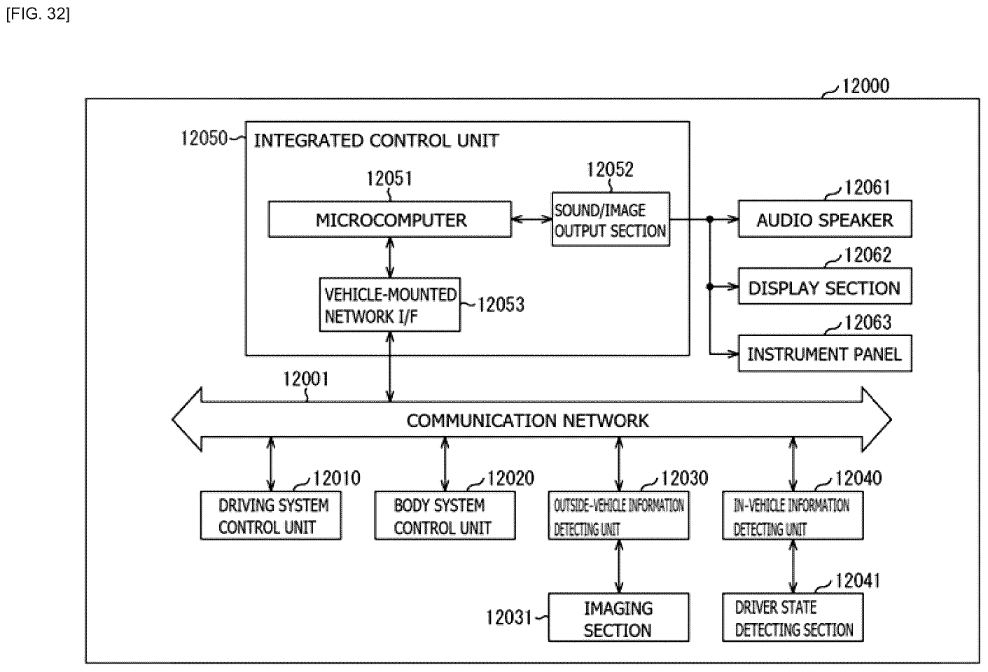

FIG. 32 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 32, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 32, an audio speaker 12061, a display section 12062, and an instrument panel 12063 are illustrated as the output device. The display section 12062 may, for example, include at least one of an on-board display and a head-up display.

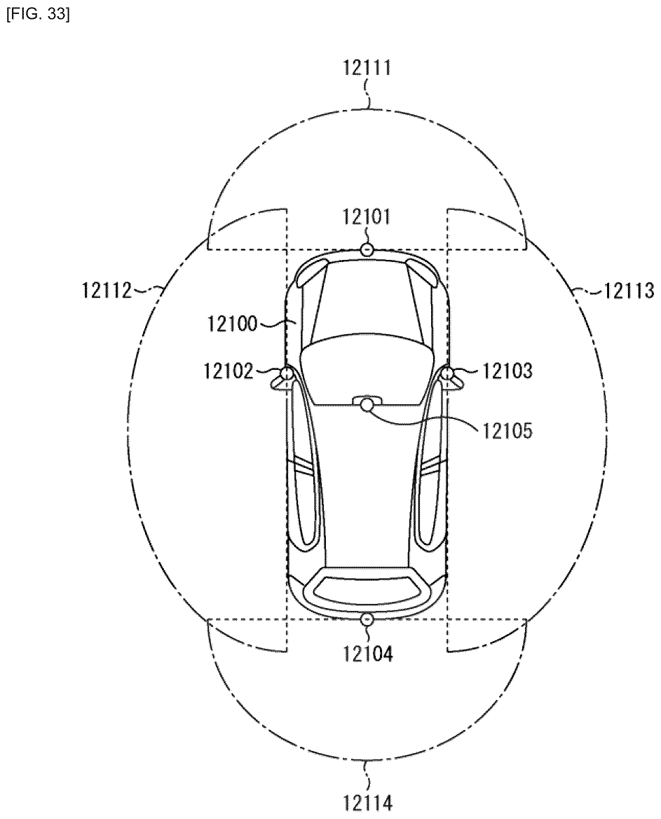

FIG. 33 is a diagram depicting an example of the installation position of the imaging section 12031.

In FIG. 33, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 33 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the mobile object control system to which the technology according to the present disclosure is applicable has been described above. The technology according to the present disclosure is applicable to the imaging section 12031 among the above-described structural elements. Specifically, for example, the photodetection device 1 is applicable to the imaging section 1203. It is possible to obtain a high-resolution captured image by applying the technology according to the present disclosure to the imaging section 12031. Therefore, it is possible to perform high-precision control utilizing the captured image in the mobile object control system.

### (Example of Application to Endoscopic Surgery System)

The technology according to the present disclosure (present technology) is applicable to various products. For example, the technology according to the present disclosure is applicable to an endoscopic surgery system.

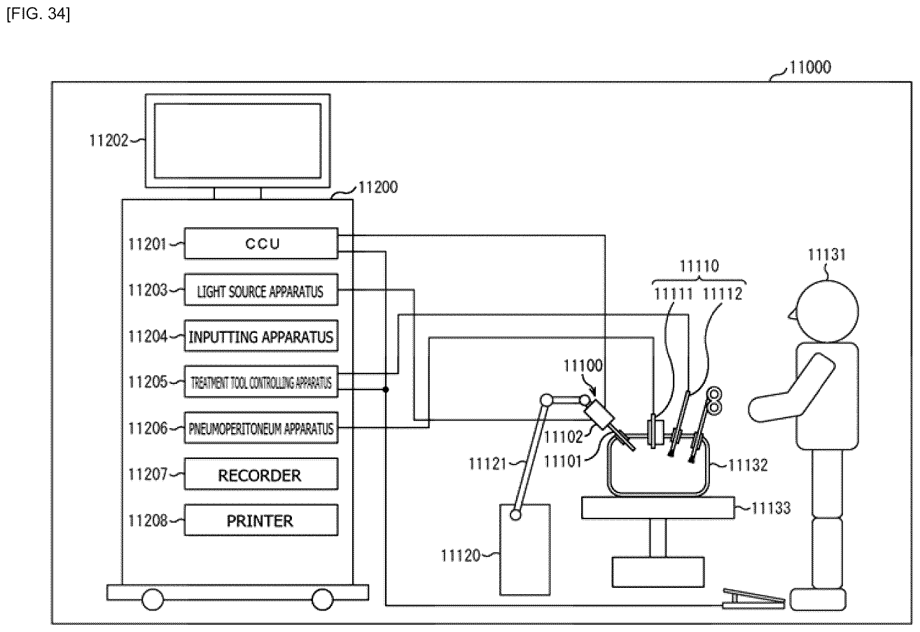

FIG. 34 is a view depicting an example of a schematic configuration of an endoscopic surgery system to which the technology according to an embodiment of the present disclosure (present technology) can be applied.

In FIG. 34, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

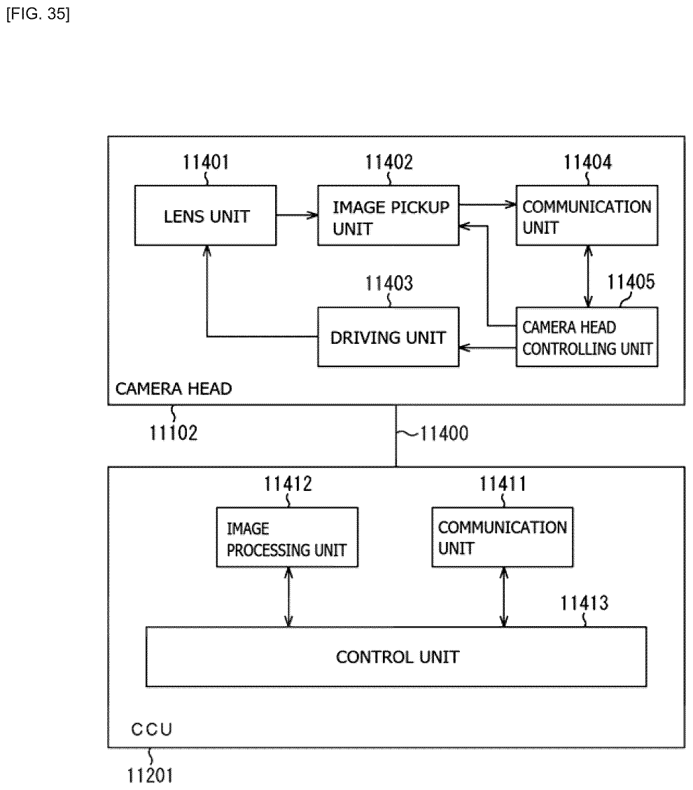

FIG. 35 is a block diagram depicting an example of a functional configuration of the camera head 11102 and the CCU 11201 depicted in FIG. 34.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure is applicable has been described above. The technology according to the present disclosure is favorably applicable to the image pickup unit 11402 provided to the camera head 11102 of the endoscope 11100 among the above-described components. The application of the technology according to the present disclosure to the image pickup unit 11402 makes it possible to sensitize the image pickup unit 11402 and provide the high-resolution endoscope 11100.

The present technology has been described above with reference to the embodiments, modifications, usage examples, and application examples. However, the present technology is not limited thereto, and various kinds of modifications thereof can be made. For example, the above modifications have been described as the modifications of the embodiments. In addition, structural elements according to the respective modifications can be used in combination as appropriate.

The photodetection device according to an embodiment of the present disclosure includes: a light-receiving element configured to receive light and generate a signal; a generation section configured to generate a first signal based on the signal generated by the light-receiving element; and a control section configured to control supply of electric current to the light-receiving element on the basis of pulse width of the first signal. This makes it possible to adjust the pulse width of the signal S2 and shorten the dead time. This makes it possible to provide the photodetection device 1 having high detection performance.

It is to be noted that the effects described herein are only for illustrative purposes and there may be other effects. In addition, the present technology may be configured as follows.

(1)

A photodetection device including:
a light-receiving element configured to receive light and generate a signal;
a generation section configured to generate a first signal based on the signal generated by the light-receiving element; and
a control section configured to control supply of electric current to the light-receiving element on the basis of pulse width of the first signal.
   (2)

The photodetection device according to (1), in which the control section is configured to control the supply of the electric current to the light-receiving element and adjust the pulse width of the first signal.

(3)

The photodetection device according to (1) or (2), further including
a supply section configured to supply the electric current to the light-receiving element,
in which the control section is configured to change the electric current to be supplied from the supply section, on the basis of the pulse width of the first signal.
   (4)

The photodetection device according to any one of (1) to (3), further including
a capacitor section configured to electrically couple to the light-receiving element,
in which the control section is configured to control the capacitor section on the basis of the pulse width of the first signal.
   (5)

The photodetection device according to any one of (1) to (4), further including
a switch configured to electrically couple the light-receiving element and an electric power source line to each other on the basis of the first signal.
   (6)

The photodetection device according to (5), further including
a first delay circuit configured to output, to the switch, a signal in which the first signal is delayed,
in which the control section is configured to change an amount of delay in the first delay circuit, on the basis of the pulse width of the first signal.
   (7)

A photodetection device including:
a light-receiving element configured to receive light and generate a signal;
a generation section configured to generate a first signal based on the signal generated by the light-receiving element; and
a control section configured to control the generation section on the basis of pulse width of the first signal.
   (8)

The photodetection device according to (7), in which the control section is configured to control an amount of delay of a signal in the generation section and adjust the pulse width of the first signal.

(9)

The photodetection device according to (7) or (8), in which
the generation section includes a second delay circuit configured to output the first signal, and
the control section is configured to change an amount of delay in the second delay circuit, on the basis of the pulse width of the first signal.
   (10)

The photodetection device according to any one of (1) to (9), in which the light-receiving element is configured to generate a signal in response to reception of a photon.

(11)

The photodetection device according to any one of (1) to (10), further including
a detection section configured to detect the pulse width of the first signal.
   (12)

The photodetection device according to (11), further including
a comparison section configured to compare the pulse width of the first signal detected by the detection section with a reference value.
   (13)

The photodetection device according to (12), further including
a signal retaining section configured to retain a second signal based on a result of the comparison made by the comparison section.
   (14)

The photodetection device according to any one of (1) to (13), further including
a plurality of pixels, each of which includes the light-receiving element and the generation section,
in which the control section is configured to control the pixels in response to the second signal.
   (15)

The photodetection device according to (14), in which the signal retaining section is provided for each of the pixels.

(16)

The photodetection device according to (14) or (15), in which the control section is provided for each of the pixels.

(17)

The photodetection device according to any one of (1) to (16), further including
a determination section configured to determine whether or not to control the pixels on the basis of the pulse width of the first signal.
   (18)

The photodetection device according to (17), in which the determination section is configured to determine, on the basis of illuminance of incident light, whether or not to control the pixels on the basis of the pulse width of the first signal.

(19)

The photodetection device according to any one of (1) to (18), in which the generation section includes an inverter circuit.

(20)

The photodetection device according to any one of (1) to (19), in which the light-receiving element is a single-photon avalanche diode.

The present application claims the benefit of Japanese Priority Patent Application JP2022-037314 filed with the Japan Patent Office on Mar. 10, 2022, the entire contents of which are incorporated herein by reference.

It should be understood by those skilled in the art that various modifications, combinations, sub-combinations and alternations may occur depending on design requirements and other factors insofar as they are within the scope of the appended claims or the equivalents thereof.

1. A photodetection device comprising:
a light-receiving element configured to receive light and generate a signal;
a generation section configured to generate a first signal based on the signal generated by the light-receiving element; and
a control section configured to control supply of electric current to the light-receiving element on a basis of pulse width of the first signal.

2. The photodetection device according to claim 1, wherein the control section is configured to control the supply of the electric current to the light-receiving element and adjust the pulse width of the first signal.

3. The photodetection device according to claim 1, further comprising
a supply section configured to supply the electric current to the light-receiving element,
wherein the control section is configured to change the electric current to be supplied from the supply section, on a basis of the pulse width of the first signal.

4. The photodetection device according to claim 1, further comprising
a capacitor section configured to electrically couple to the light-receiving element,
wherein the control section is configured to control the capacitor section on a basis of the pulse width of the first signal.

5. The photodetection device according to claim 1, further comprising
a switch configured to electrically couple the light-receiving element and an electric power source line to each other on a basis of the first signal.

6. The photodetection device according to claim 5, further comprising
a first delay circuit configured to output, to the switch, a signal in which the first signal is delayed,
wherein the control section is configured to change an amount of delay in the first delay circuit, on a basis of the pulse width of the first signal.

7. A photodetection device comprising:
a light-receiving element configured to receive light and generate a signal;
a generation section configured to generate a first signal based on the signal generated by the light-receiving element; and
a control section configured to control the generation section on a basis of pulse width of the first signal.

8. The photodetection device according to claim 7, wherein the control section is configured to control an amount of delay of a signal in the generation section and adjust the pulse width of the first signal.

9. The photodetection device according to claim 7, wherein
the generation section includes a second delay circuit configured to output the first signal, and
the control section is configured to change an amount of delay in the second delay circuit, on a basis of the pulse width of the first signal.

10. The photodetection device according to claim 1, wherein the light-receiving element is configured to generate a signal in response to reception of a photon.

11. The photodetection device according to claim 1, further comprising
a detection section configured to detect the pulse width of the first signal.

12. The photodetection device according to claim 11, further comprising
a comparison section configured to compare the pulse width of the first signal detected by the detection section with a reference value.

13. The photodetection device according to claim 12, further comprising
a signal retaining section configured to retain a second signal based on a result of the comparison made by the comparison section.

14. The photodetection device according to claim 13, further comprising
a plurality of pixels, each of which includes the light-receiving element and the generation section,
wherein the control section is configured to control the pixels in response to the second signal.

15. The photodetection device according to claim 14, wherein the signal retaining section is provided for each of the pixels.

16. The photodetection device according to claim 15, wherein the control section is provided for each of the pixels.

17. The photodetection device according to claim 14, further comprising
a determination section configured to determine whether or not to control the pixels on a basis of the pulse width of the first signal.

18. The photodetection device according to claim 17, wherein the determination section is configured to determine, on a basis of illuminance of incident light, whether or not to control the pixels on a basis of the pulse width of the first signal.

19. The photodetection device according to claim 1, wherein the generation section includes an inverter circuit.

20. The photodetection device according to claim 1, wherein the light-receiving element comprises a single-photon avalanche diode.
